(19) United States
(12) Patent Application Publication
(10) Pub. No.: US 2024/0392148 A1
(43) Pub. Date: Nov. 28, 2024

(54) PATTERN FORMING METHOD AND ARTICLE MANUFACTURING METHOD

(71) Applicant: CANON KABUSHIKI KAISHA, Tokyo (JP)

(72) Inventor: TOSHIKI ITO, Kanagawa (JP)

(21) Appl. No.: 18/797,608

(22) Filed: Aug. 8, 2024

Related U.S. Application Data
(63) Continuation of application No. PCT/JP2023/001332, filed on Jan. 18, 2023.

(30) Foreign Application Priority Data
Feb. 28, 2022 (JP) 2022-030178

(51) Int. Cl. C09D 11/101; C09D 11/107; C09D 11/30

(52) U.S. Cl. CPC C09D 11/101; C09D 11/107; C09D 11/30

(57) ABSTRACT

A pattern forming method is provided. A thickness of a residual film sandwiched between a most projecting portion of a pattern of the mold and the substrate is not less than 50 nm, and a height difference of the unevenness of the mold is not more than the thickness of the residual film. The method includes a forming step of forming an inversion layer on unevenness transferred from the mold onto a cured film, a removing step of removing an upper layer portion of the inversion layer such that a top surface of a convex portion of the unevenness formed on the cured film is exposed, and an etching step of, using the inversion layer buried in the concave portion as a mask, etching the cured film up to a surface of the substrate to form an inverted pattern.

### CROSS-REFERENCE TO RELATED APPLICATIONS

This application is a Continuation of International Patent Application No. PCT/JP2023/001332, filed Jan. 18, 2023, which claims the benefit of Japanese Patent Application No. 2022-030178 filed Feb. 28, 2022, both of which are hereby incorporated by reference herein in their entirety.

### BACKGROUND OF THE INVENTION

### Field of the Invention

The present invention relates to a pattern forming method and an article manufacturing method.

### Background Art

For semiconductor devices and MEMS, requirements of micronization are increasing, and as a micropatterning technique, an imprint technique (optical imprint technique) has received a great deal of attention as a microfabrication technique. In the imprint technique, a curable composition is cured in a state in which a mold with a fine concave-convex pattern formed on the surface is in contact with the curable composition supplied (applied) onto a substrate. Thus, the pattern of the mold is transferred to the cured film of the curable composition, thereby forming the pattern on the substrate. According to the imprint technique, it is possible to form, on a substrate, a fine pattern (structure) on a several nanometer order (see PTL 1).

An example of a pattern forming method using the imprint technique will be described. First, a curable composition in liquid form is discretely dropped (arranged), using an inkjet method, in a pattern formation region on a substrate. The droplets of the curable composition arranged in the pattern formation region spread on the substrate. This phenomenon is called pre-spreading. Next, a mold is brought into contact with (pressed against) the curable composition on the substrate. Thus, the droplets of the curable composition spread to the whole region of the gap between the substrate and the mold in a direction parallel to the substrate surface by a capillary phenomenon. This phenomenon is called spreading. Also, by the capillary phenomenon, the curable composition fills concave portions that form the pattern of the mold. This phenomenon is called filling. Note that the time until spreading and filling are completed is called a filling time. If the filling of the curable composition is completed, the curable composition is irradiated with light to cure the curable composition. Then, the mold is released from the cured curable composition on the substrate. By executing these steps, the pattern of the mold is transferred to the curable composition on the substrate, and the pattern of a cured film of the curable composition is formed.

When processing a substrate using a pattern obtained using the imprint technique as a mask, a step called an inversion process can be applied. PTL 2 discloses the following inversion process step. An inversion layer is formed on a concave-convex pattern (inversion layer forming step), and an inversion layer material is buried in concave portions. The inversion layer material is stacked on the upper portions of convex portions of the concave-convex pattern as well to form a surplus inversion layer. The surplus inversion layer is removed (surplus inversion layer removing step) to expose the top surface of the convex portion of the concave-convex pattern of the cured film of the curable composition, thereby exposing the inversion layer buried in the concave portions. The residual film of the concave-convex pattern and a carbon-based material layer that is a lower layer are etched using the exposed inversion layer as a mask, thereby forming an inverted pattern (lower layer etching step). The residual film in this specification is the residual film remaining between the substrate and concave portions of the cured film of the curable composition (convex portions of a mold pattern).

### CITATION LIST

### Patent Literature

PTL 1: Japanese Patent No. 6584578
PTL 2: Japanese Patent Laid-Open No. 2016-162862
PTL 3: Japanese Patent Laid-Open No. 2007-186570
PTL 4: Japanese Patent Laid-Open No. 2009-503139

### Non Patent Literature

NPL 1: J. Electrochem. Soc., 130, p. 143 (1983)

In the conventional inversion process, a layer such as a spin-on-carbon (SOC) layer whose dry etching resistance is higher than that of the curable composition needs to be formed under the curable composition for imprint.

Also, in the conventional inversion process, the residual film of the curable composition with a low dry etching resistance needs to be minimized. Hence, if a foreign substance is sandwiched between the mold and the lower layer, the mold is broken.

### SUMMARY OF THE INVENTION

The present invention has been made in consideration of the problem of the conventional technique and provides a new technique concerning a pattern forming method and an article manufacturing method.

According to an aspect of the present invention, there is provided a pattern forming method including an arranging step of arranging, on a substrate, a curable composition (A) containing at least a polymerizable compound (a), a contact step of, after the arranging step, bringing the curable composition (A) on the substrate into contact with a mold having unevenness, a curing step of, after the contact step, curing the curable composition (A) to form a cured film, and a separation step of, after the curing step, separating the curable composition (A) and the mold, characterized in that a thickness of a residual film sandwiched between the substrate and a most projecting portion of the concave-convex pattern of the mold is not less than 50 nm, and a height difference of the unevenness of the mold is not more than the thickness of the residual film, and the pattern forming method further comprises a forming step of forming an inversion layer on unevenness transferred from the mold onto the cured film, a removing step of, in a state in which the inversion layer is buried in a concave portion of the unevenness formed on the cured film, removing an upper layer portion of the inversion layer such that a top surface of a convex portion of the unevenness formed on the cured film is exposed, and an etching step of, using the inversion layer buried in the concave portion as a mask, etching the cured film up to a surface of the substrate to form an inverted pattern.

Further features of the present invention will become apparent from the following description of exemplary embodiments with reference to the attached drawings.

### BRIEF DESCRIPTION OF THE DRAWINGS

FIG. 1 is a view for explaining an arranging step to a separation step of a pattern forming method according to the present invention.

FIG. 2 is a view for comparatively explaining the breaking behavior of a mold pattern by a foreign substance.

FIG. 3 is a view for explaining an inversion process of the pattern forming method according to the present invention.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

As a result of earnest examinations, the present inventors devised an inversion process that does not need an SOC layer in an imprint technique. The present inventors also found that in the inversion process, the possibility of mold pattern breakage caused by a foreign substance unintentionally sandwiched between the mold and the substrate is low.

### [Curable Composition]

A curable composition (A) according to the present disclosure is a composition containing at least a component (a) as a polymerizable compound, and a component (b) as a photopolymerization initiator. The curable composition (A) according to the present disclosure may further contain a nonpolymerizable compound (c), and a component (d) as a solvent.

In this specification, a cured film means a film cured by polymerizing the curable composition (A) on a substrate. Note that the cured film has a pattern shape on the surface.

### <Component (a): Polymerizable Compound>

The component (a) is a polymerizable compound. In this specification, the polymerizable compound is a compound that reacts with a polymerizing factor (for example, a radical) generated from a polymerization initiator (the component (b)), and forms a film made of a polymer compound by a chain reaction (polymerization reaction).

An example of the polymerizable compound as described above is a radical polymerizable compound. The polymerizable compound as the component (a) can be formed by only one type of a polymerizable compound, and can also be formed by a plurality of types of polymerizable compounds.

Examples of the radical polymerizable compound are a (meth)acrylic compound, a styrene-based compound, a vinyl-based compound, an allylic compound, a fumaric compound, and a maleic compound. The (meth)acrylic compound is a compound having one or more acryloyl groups or methacryloyl groups. Examples of a monofunctional (meth)acrylic compound having one acryloyl group or methacryloyl group are as follows, but the compound is not limited to these examples.

Phenoxyethyl (meth)acrylate, phenoxy-2-methylethyl (meth)acrylate, phenoxyethoxyethyl (meth)acrylate, 3-phenoxy-2-hydroxypropyl (meth)acrylate, 2-phenylphenoxyethyl (meth)acrylate, 4-phenylphenoxyethyl (meth)acrylate, 3-(2-phenylphenyl)-2-hydroxypropyl (meth)acrylate, (meth)acrylate of EO-modified p-cumylphenol, 2-bromophenoxyethyl (meth)acrylate, 2,4-dibromophenoxyethyl (meth)acrylate, 2,4,6-tribromophenoxyethyl (meth)acrylate, EO-modified phenoxy (meth)acrylate, PO-modified phenoxy (meth)acrylate, polyoxyethylenenonylphenylether (meth)acrylate, isobornyl (meth)acrylate, 1-adamantyl (meth)acrylate, 2-methyl-2-adamantyl (meth)acrylate, 2-ethyl-2-adamantyl (meth)acrylate, bornyl (meth)acrylate, tricyclodecanyl (meth)acrylate, dicyclopentanyl (meth)acrylate, dicyclopentenyl (meth)acrylate, cyclohexyl (meth)acrylate, 4-butylcyclohexyl (meth)acrylate, acryloylmorpholine, 2-hydroxyethyl (meth)acrylate, 2-hydroxypropyl (meth)acrylate, 2-hydroxybutyl (meth)acrylate, methyl (meth)acrylate, ethyl (meth)acrylate, propyl (meth)acrylate, isopropyl (meth)acrylate, butyl (meth)acrylate, amyl (meth)acrylate, isobutyl (meth)acrylate, t-butyl (meth)acrylate, pentyl (meth)acrylate, isoamyl (meth)acrylate, hexyl (meth)acrylate, heptyl (meth)acrylate, octyl (meth)acrylate, isooctyl (meth)acrylate, 2-ethylhexyl (meth)acrylate, nonyl (meth)acrylate, decyl (meth)acrylate, isodecyl (meth)acrylate, undecyl (meth)acrylate, dodecyl (meth)acrylate, lauryl (meth)acrylate, stearyl (meth)acrylate, isostearyl (meth)acrylate, benzyl (meth)acrylate, tetrahydrofurfuryl (meth)acrylate, butoxyethyl (meth)acrylate, ethoxydiethyleneglycol (meth)acrylate, polyethyleneglycol mono(meth)acrylate, polypropyleneglycol mono(meth)acrylate, methoxyethyleneglycol (meth)acrylate, ethoxyethyl (meth)acrylate, methoxypolyethyleneglycol (meth)acrylate, methoxypolypropyleneglycol (meth)acrylate, diacetone (meth)acrylamide, isobutoxymethyl (meth)acrylamide, N,N-dimethyl (meth)acrylamide, t-octyl (meth)acrylamide, dimethylaminoethyl (meth)acrylate, diethylaminoethyl (meth)acrylate, 7-amino-3,7-dimethyloctyl (meth)acrylate, N,N-diethyl (meth)acrylamide, N,N-dimethylaminopropyl (meth)acrylamide, 1- or 2-naphthyl (meth)acrylate, 1- or 2-naphthylmethyl (meth)acrylate, 3- or 4-phenoxybenzyl (meth)acrylate, and cyanobenzyl (meth)acrylate.

Examples of commercially available products of the above-described monofunctional (meth)acrylic compounds are as follows, but the products are not limited to these examples.

ARONIX® M101, M102, M110, M111, M113, M117, M5700, TO-1317, M120, M150, and M156 (manufactured by TOAGOSEI); MEDOL10, MIBDOL10, CHDOL10, MMDOL30, MEDOL30, MIBDOL30, CHDOL30, LA, IBXA, 2-MTA, HPA, and Viscoat #150, #155, #158, #190, #192, #193, #220, #2000, #2100, and #2150 (manufactured by OSAKA ORGANIC CHEMICAL INDUSTRY); Light Acrylate BO-A, EC-A, DMP-A, THF-A, HOP-A, HOA-MPE, HOA-MPL, PO-A, P-200A, NP-4EA, NP-8EA, Epoxy Ester M-600A, POB-A, and OPP-EA (manufactured by KYOEISHA CHEMICAL); KAYARAD® TC110S, R-564, and R-128H (manufactured by NIPPON KAYAKU); NK Ester AMP-10G, AMP-20G, and A-LEN-10 (manufactured by SHIN-NAKAMURA CHEMICAL); FA-511A, 512A, and 513A (manufactured by Hitachi Chemical); PHE, CEA, PHE-2, PHE-4, BR-31, BR-31M, and BR-32 (manufactured by DKS); VP (manufactured by BASF); and ACMO, DMAA, and DMAPAA (manufactured by Kohjin).

Examples of a polyfunctional (meth)acrylic compound having two or more acryloyl groups or methacryloyl groups are as follows, but the compound is not limited to these examples.

Trimethylolpropane di(meth)acrylate, trimethylolpropane tri(meth)acrylate, EO-modified trimethylolpropane tri(meth)acrylate, PO-modified trimethylolpropane tri(meth)acrylate, EO- and PO-modified trimethylolpropane tri(meth)acrylate, dimethylol tricyclodecane di(meth)acrylate, pentaerythritol tri(meth)acrylate, pentaerythritol tetra(meth)acrylate, ethylene glycol di(meth)acrylate, tetraethylene glycol di(meth)acrylate, polyethylene glycol di(meth)acrylate, polypropylene glycol di(meth)acrylate, 1,4-butanediol di(meth)acrylate, 1,6-hexanediol di(meth)acrylate, neopentyl glycol di(meth)acrylate, 1,9-nonanediol di(meth)acrylate, 1,10-decanediol di(meth)acrylate, 1,3-adamantanedimethanol di(meth)acrylate, tris(2-hydoxyethyl) isocyanurate tri(meth)acrylate, tris(acryloyloxy) isocyanurate, bis(hydroxymethyl)tricyclodecane di(meth)acrylate, dipentaerythritol penta(meth)acrylate, dipentaerythritol hexa(meth)acrylate, EO-modified 2,2-bis(4-((meth)acryloxy)phenyl) propane, PO-modified 2,2-bis(4-((meth)acryloxy)phenyl) propane, EO- and PO-modified 2,2-bis(4-((meth)acryloxy)phenyl) propane, o-, m-, or p-benzene di(meth)acrylate, and o-, m-, or p-xylylene di(meth)acrylate.

Examples of commercially available products of the above-described polyfunctional (meth)acrylic compounds are as follows, but the products are not limited to these examples.

Yupimer® UV SA1002 and SA2007 (manufactured by Mitsubishi Chemical); Viscoat #195, #230, #215, #260, #335HP, #295, #300, #360, #700, GPT, and 3PA (manufactured by OSAKA ORGANIC CHEMICAL INDUSTRY); Light Acrylate 4EG-A, 9EG-A, NP-A, DCP-A, BP-4EA, BP-4PA, TMP-A, PE-3A, PE-4A, and DPE-6A (manufactured by KYOEISHA CHEMICAL); KAYARAD® PET-30, TMPTA, R-604, DPHA, DPCA-20, -30, -60, and -120, HX-620, D-310, and D-330 (manufactured by NIPPON KAYAKU); ARONIX® M208, M210, M215, M220, M240, M305, M309, M310, M315, M325, and M400 (manufactured by TOAGOSEI); Ripoxy® VR-77, VR-60, and VR-90 (manufactured by Showa Highpolymer); and OGSOL EA-0200 and OGSOL EA-0300 (manufactured by Osaka Gas Chemicals).

Note that in the above-described compound county, (meth)acrylate means acrylate or methacrylate having an alcohol residue equal to acrylate. A (meth)acryloyl group means an acryloyl group or a methacryloyl group having an alcohol residue equal to the acryloyl group. EO indicates ethylene oxide, and an EO-modified compound A indicates a compound in which a (meth)acrylic acid residue and an alcohol residue of a compound A bond via the block structure of an ethylene oxide group. Also, PO indicates a propylene oxide, and a PO-modified compound B indicates a compound in which a (meth)acrylic acid residue and an alcohol residue of a compound B bond via the block structure of a propylene oxide group.

Practical examples of the styrene-based compound are as follows, but the compound is not limited to these examples.

Alkylstyrene such as styrene, 2,4-dimethyl-α-methylstyrene, o-methylstyrene, m-methylstyrene, p-methylstyrene, 2,4-dimethylstyrene, 2,5-dimethylstyrene, 2,6-dimethylstyrene, 3,4-dimethylstyrene, 3,5-dimethylstyrene, 2,4,6-trimethylstyrene, 2,4,5-trimethylstyrene, pentamethylstyrene, o-ethylstyrene, m-ethylstyrene, p-ethylstyrene, diethylstyrene, triethylstyrene, propylstyrene 2,4-diisopropylstyrene, butylstyrene, hexylstyrene, heptylstyrene, and octylstyrene; styrene halide such as fluorostyrene, o-chlorostyrene, m-chlorostyrene, p-chlorostyrene, o-bromostyrene, m-bromostyrene, p-bromostyrene, dibromostyrene, and iodostyrene; and a compound having a styryl group as a polymerizable functional group, such as nitrostyrene, acetylstyrene, o-methoxystyrene, m-methoxystyrene, p-methoxystyrene, o-hydroxystyrene, m-hydroxystyrene, p-hydroxystyrene, 2-vinylbiphenyl, 3-vinylbiphenyl, 4-vinylbiphenyl, 1-vinylnaphthalene, 2-vinylnaphthalene, 4-vinyl-p-terphenyl, 1-vinylanthracene, α-methylstyrene, o-isopropenyltoluene, m-isopropenyltoluene, p-isopropenyltoluene, 2,3-dimethyl-α-methylstyrene, 3,5-dimethyl-α-methylstyrene, p-isopropyl-α-methylstyrene, α-ethylstyrene, α-chlorostyrene, divinylbenzene, diisopropylbenzene, and divinylbiphenyl.

Practical examples of the vinyl-based compound are as follows, but the compound is not limited to these examples.

Vinylpyridine, vinylpyrrolidone, vinylcarbazole, vinyl acetate, and acrylonitrile; conjugated diene monomers such as butadiene, isoprene, and chloroprene; vinyl halide such as vinyl chloride and vinyl bromide; a compound having a vinyl group as a polymerizable functional group, for example, vinylidene halide such as vinylidene chloride, vinyl ester of organic carboxylic acid and its derivative (for example, vinyl acetate, vinyl propionate, vinyl butyrate, vinyl benzoate, and divinyl adipate), and (meth)acrylonitrile.

Note that in this specification, (meth)acrylonitrile is a general term for acrylonitrile and methacrylonitrile.

Examples of the allylic compound are as follows, but the compound is not limited to these examples.

Allyl acetate, allyl benzoate, diallyl adipate, diallyl terephthalate, diallyl isophthalate, and diallyl phthalate.

Examples of the fumaric compound are as follows, but the compound is not limited to these examples.

Dimethyl fumarate, diethyl fumarate, diisopropyl fumarate, di-sec-butyl fumarate, diisobutyl fumarate, di-n-butyl fumarate, di-2-ethylhexyl fumarate, and dibenzyl fumarate.

Examples of the maleic compound are as follows, but the compound is not limited to these examples.

Dimethyl maleate, diethyl maleate, diisopropyl maleate, di-sec-butyl maleate, diisobutyl maleate, di-n-butyl maleate, di-2-ethylhexyl maleate, and dibenzyl maleate.

Other examples of the radical polymerizable compound are as follows, but the compound is not limited to these examples.

Dialkylester of itaconic acid and its derivative (for example, dimethyl itaconate, diethyl itaconate, diisopropyl itaconate, di-sec-butyl itaconate, diisobutyl itaconate, di-n-butyl itaconate, di-2-ethylhexyl itaconate, and dibenzyl itaconate), an N-vinylamide derivative of organic carboxylic acid (for example, N-methyl-N-vinylacetamide), and maleimide and its derivative (for example, N-phenylmaleimide and N-cyclohexylmaleimide).

If the component (a) is formed by a plurality of types of compounds having one or more polymerizable functional groups, a monofunctional compound and a polyfunctional compound are preferably included. This is because if a monofunctional compound and a polyfunctional compound are combined, a cured film having well-balanced performance, for example, a high mechanical strength, a high dry etching resistance, and a high heat resistance can be obtained.

The polymerizable compound (a) preferably has low volatility. Hence, in the polymerizable compound (a) that can contain a plurality of types of compounds, the boiling points of all the compounds at normal pressure are preferably 250° C. or more, more preferably 300° C. or more, and further preferably 350° C. or more. The boiling point of the polymerizable compound (a) is almost correlated with the molecular weight. Therefore, the molecular weights of all the polymerizable compounds (a) are preferably 200 or more, more preferably 240 or more, and further preferably 250 or more. However, even when the molecular weight is 200 or less, the compound is preferably usable as the polymerizable compound (a) of the present disclosure if the boiling point is 250° C. or more.

In addition, the vapor pressure at 80° C. of the polymerizable compound (a) is preferably 0.001 mmHg or less. This is so because, although it is favorable to heat the curable composition when accelerating volatilization of the solvent (d) (to be described later), it is necessary to suppress volatilization of the polymerizable compound (a) during heating.

Note that the boiling point and the vapor pressure of each organic compound at normal pressure can be calculated by, for example, Hansen Solubility Parameters in Practice (HSPiP) 5th Edition. 5.3.04.

<Ohnishi Parameter (OP) of Component (a)>

It is known that a dry etching rate V of an organic compound, a number N of all atoms in the organic compound, a number N_{C} of all carbon atoms in a composition, and a number N_{O} of all oxygen atoms in the composition have a relationship of equation (1) below (NPL 1).

$$V ∝ N / ( {N}_{C} - {N}_{o} ) \qquad ( 1 )$$

where N/(N_{C}−N_{O}) is also called “Ohnishi Parameter” (to be referred to as “OP” hereinafter). For example, PTL 3 describes a technique of obtaining a photocurable composition having a high dry etching resistance by using a polymerizable compound having a small OP.

Equation (1) indicates that an organic compound having many oxygen atoms in a molecule or having few aromatic ring structures or alicyclic structures has a large OP and a high dry etching rate.

In the curable composition, the OP of the component (a) is preferably 2.00 or more and 3.00 or less, more preferably 2.00 or more and 2.80 or less, and particularly preferably 2.00 or more and 2.60 or less. When the OP is 3.00 or less, the cured film of the curable composition (A) has a high dry etching resistance. Also, when the OP is 2.00 or more, the cured film of the curable composition (A) can easily be removed when the underlayer is processed by using the cured film of the curable composition (A). When the component (a) is formed by a plurality of types polymerizable compounds a₁, a₂, . . . , aₙ, the OP is calculated as a weighted average value (molar fraction weighted average value) based on the molar fraction as indicated by equation (2) below:

$$OP = {\sum }_{i = n} {n}_{i} {OP}_{i} = {n}_{1} {OP}_{1} + {n}_{2} {OP}_{2} + … + {n}_{n} {OP}_{n} \qquad ( 2 )$$

where OPₙ is the OP of the component aₙ, and nₙ is the molar fraction occupied by the component aₙ in the entire component (a).

To set the OP of the component (a) to 2.00 or more and 3.00 or less, a compound having a cyclic structure such as an aromatic structure, an aromatic heterocyclic structure, or an alicyclic structure is preferably contained at least as the component (a).

The carbon number of the aromatic structure is preferably 6 to 22, more preferably 6 to 18, and further preferably 6 to 10. Practical examples of the aromatic ring are as follows.

A benzene ring, a naphthalene ring, an anthracene ring, a phenanthrene ring, a phenalene ring, a fluorene ring, a benzocyclooctene ring, an acenaphthylene ring, a biphenylene ring, an indene ring, an indane ring, a triphenylene ring, a pyrene ring, a chrysene ring, a perylene ring, and a tetrahydronaphthalene ring.

Note that, of the above-described aromatic rings, a benzene ring or a naphthalene ring is preferable, and a benzene ring is more preferable. The aromatic ring can have a structure in which a plurality of rings are connected. Examples are a biphenyl ring and a bisphenyl ring.

The carbon number of the aromatic heterocyclic structure is preferably 1 to 12, more preferably 1 to 6, and further preferably 1 to 5. Practical examples of the aromatic heterocycle are as follows.

A thiophene ring, a furan ring, a pyrolle ring, an imidazole ring, a pyrazole ring, a triazole ring, a tetrazole ring, a thiazole ring, a thiadiazole ring, an oxadiazole ring, an oxazole ring, a pyridine ring, a pyrazine ring, a pyrimidine ring, pyridazine ring, an isoindole ring, an indole ring, an indazole ring, a purine ring, a quinolizine ring, an isoquinoline ring, a quinoline ring, a phthalazine ring, a naphthyridine ring, a quinoxaline ring, a quinazoline ring, a cinnoline ring, a carbazole ring, an acridine ring, a phenazine ring, a phenothiazine ring, a phenoxathiine ring, and a phenoxazine ring.

The carbon number of the alicyclic structure is preferably 3 or more, more preferably 4 or more, and further preferably 6 or more. In addition, the carbon number of the alicyclic structure is preferably 22 or less, more preferably 18 or less, further preferably 6 or less, and still further preferably 5 or less. Practical examples are as follows.

A cyclopropane ring, a cyclobutane ring, a cyclobutene ring, a cyclopentane ring, a cyclohexane ring, a cyclohexene ring, a cycloheptane ring, a cyclooctane ring, a dicyclopentadiene ring, a spirodecane ring, a spirononane ring, a tetrahydro dicyclopentadiene ring, an octahydronaphthalene ring, a decahydronaphthalene ring, a hexahydroindane ring, a bornane ring, a norbornane ring, a norbornene ring, an isobornane ring, a tricyclodecane ring, a tetracyclododecane ring, and an adamantane ring.

Practical examples of the polymerizable compound (a) having a cyclic structure and a boiling point of 250° C. or more are as follows, but the compound is not limited to these examples.
dicyclopentanyl acrylate (boiling point=262° C., molecular weight=206)
dicyclopentenyl acrylate (boiling point=270° C., molecular weight=204)
1,3-cyclohexanedimethanol diacrylate (boiling point=310° C., molecular weight=252)
1,4-cyclohexanedimethanol diacrylate (boiling point=339° C., molecular weight=252)
4-hexylresorcinol diacrylate (boiling point=379° C., molecular weight=302)
6-phenylhexane-1,2-diol diacrylate (boiling point=381° C., molecular weight=302)
7-phenylheptan-1,2-diol diacrylate (boiling point=393° C., molecular weight=316)
1,3-bis((2-hydroxyethoxy)methyl) cyclohexane diacrylate (boiling point=403° C., molecular weight=340)
8-phenyloctane-1,2-diol diacrylate (boiling point=404° C., molecular weight=330)
1,3-bis((2-hydroxyethoxy)methyl) benzene diacrylate (boiling point=408° C., molecular weight=334)
1,4-bis((2-hydroxyethoxy)methyl) cyclohexane diacrylate (boiling point=445° C., molecular weight=340)
3-phenoxybenzyl acrylate (mPhOBzA, OP=2.54, boiling point=367.4° C., 80° C. vapor pressure=0.0004 mmHg, molecular weight=254.3)

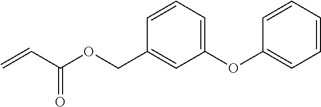 [SMILES: C=CC(=O)OCc1cccc(Oc2ccccc2)c1]

1-naphthyl acrylate (NaA, OP=2.27, boiling point=317° C., 80° C. vapor pressure=0.0422 mmHg, molecular weight=198)

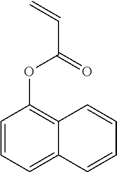

2-phenylphenoxyethyl acrylate (PhPhOEA, OP=2.57, boiling point=364.2° C., 80° C. vapor pressure=0.0006 mmHg, molecular weight=268.3)

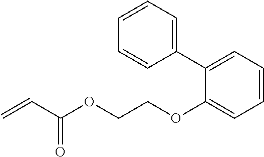 [SMILES: C=CC(=O)OCCOc1ccccc1-c1ccccc1]

1-naphthylmethyl acrylate (Na1MA, OP=2.33, boiling point=342.1° C., 80° C. vapor pressure=0.042 mmHg, molecular weight=212.2)

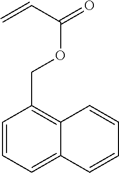 [SMILES: C=CC(=O)OCc1cccc2ccccc12]

2-naphthylmethyl acrylate (Na2MA, OP=2.33, boiling point=342.1° C., 80° C. vapor pressure=0.042 mmHg, molecular weight=212.2)

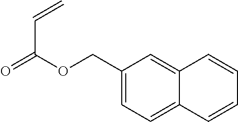 [SMILES: C=CC(=O)OCc1ccc2ccccc2c1]

4-cyanobenzyl acrylate (CNBzA, OP=2.44, boiling point=316° C., molecular weight=187)

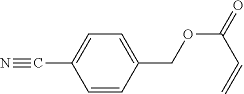

DVBzA indicated by the formula below (OP=2.50, boiling point=304.6° C., 80° C. vapor pressure=0.0848 mmHg, molecular weight=214.3)

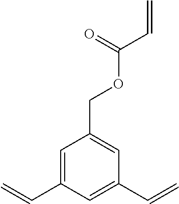 [SMILES: C=CC(=O)OCc1cc(C=C)cc(C=C)c1]

DPhPA indicated by the formula below (OP=2.38, boiling point=354.5° C., 80° C. vapor pressure=0.0022 mmHg, molecular weight=266.3)

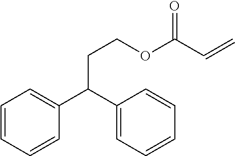 [SMILES: C=CC(=O)OCCC(c1ccccc1)c1ccccc1]

PhBzA indicated by the formula below (OP=2.29, boiling point=350.4° C., 80° C. vapor pressure=0.0022 mmHg, molecular weight=238.3)

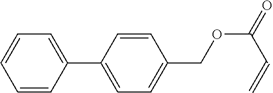 [SMILES: C=CC(=O)OCc1ccc(-c2ccccc2)cc1]

FLMA indicated by the formula below (OP=2.20, boiling point=349.3° C., 80° C. vapor pressure=0.0018 mmHg, molecular weight=250.3)

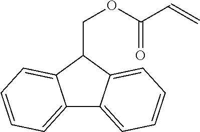 [SMILES: C=CC(=O)OCC1c2ccccc2-c2ccccc21]

ATMA indicated by the formula below (OP=2.13, boiling point=414.9° C., 80° C. vapor pressure=0.0001 mmHg, molecular weight=262.3)

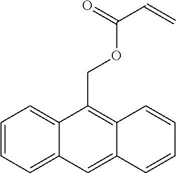 [SMILES: C=CC(=O)OCc1c2ccccc2cc2ccccc12]

DNaMA indicated by the formula below (OP=2.00, boiling point=489.4° C., 80° C. vapor pressure<0.0001 mmHg, molecular weight=338.4)

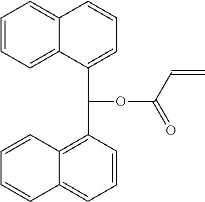 [SMILES: C=CC(=O)OC(c1cccc2ccccc12)c1cccc2ccccc12]

tricyclodecanedimethanol diacrylate (DCPDA, OP=3.29, boiling point=342° C., 80° C. vapor pressure<0.0024 mmHg, molecular weight=304)

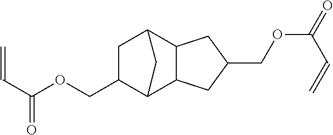 [SMILES: C=CC(=O)OCC1CC2C3CC(COC(=O)C=C)C(C3)C2C1]

m-xylylene diacrylate (mXDA, OP=3.20, boiling point=336° C., 80° C. vapor pressure<0.0043 mmHg, molecular weight=246)

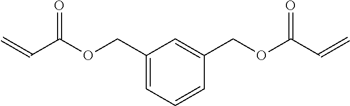 [SMILES: C=CC(=O)OCc1cccc(COC(=O)C=C)c1]

1-phenylethane-1,2-diyl diacrylate (PhEDA, OP=3.20, 80° C. vapor pressure<0.0057 mmHg, boiling point=354° C., molecular weight=246)

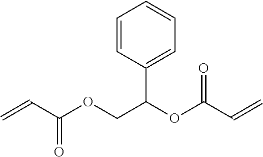 [SMILES: C=CC(=O)OCC(OC(=O)C=C)c1ccccc1]

2-phenyl-1,3-propan diol diacrylate (PhPDA, OP=3.18, boiling point=340° C., 80° C. vapor pressure<0.0017 mmHg, molecular weight=260)

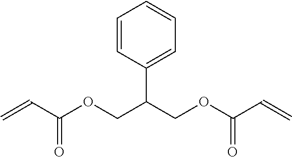 [SMILES: C=CC(=O)OCC(COC(=O)C=C)c1ccccc1]

VmXDA indicated by the formula below (OP=3.00, boiling point=372.4° C., 80° C. vapor pressure=0.0005 mmHg, molecular weight=272.3)

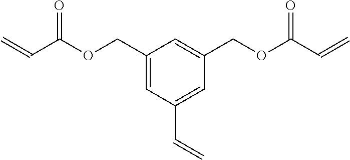 [SMILES: C=CC(=O)OCc1cc(C=C)cc(COC(=O)C=C)c1]

BPh44DA indicated by the formula below (OP=2.63, boiling point=444° C., 80° C. vapor pressure<0.0001 mmHg, molecular weight=322.3)

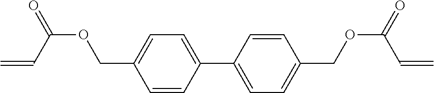 [SMILES: C=CC(=O)OCc1ccc(-c2ccc(COC(=O)C=C)cc2)cc1]

BPh43DA indicated by the formula below (OP=2.63, boiling point=439.5° C., 80° C. vapor pressure<0.0001 mmHg, molecular weight=322.3)

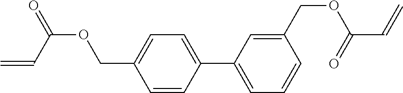 [SMILES: C=CC(=O)OCc1ccc(-c2cccc(COC(=O)C=C)c2)cc1]

DPhEDA indicated by the formula below (OP=2.63, boiling point=410° C., 80° C. vapor pressure<0.0001 mmHg, molecular weight=322.3)

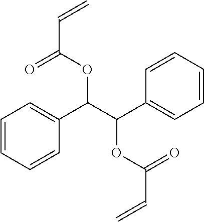 [SMILES: C=CC(=O)OC(c1ccccc1)C(OC(=O)C=C)c1ccccc1]

BPMDA indicated by the formula below (OP=2.68, boiling point=465.7° C., 80° C. vapor pressure<0.0001 mmHg, molecular weight=364.4)

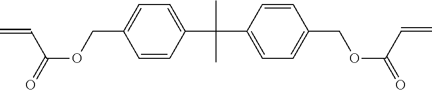 [SMILES: C=CC(=O)OCc1ccc(C(C)(C)c2ccc(COC(=O)C=C)cc2)cc1]

Na13MDA indicated by the formula below (OP=2.71, boiling point=438.8° C., 80° C. vapor pressure<0.0001 mmHg, molecular weight=296.3)

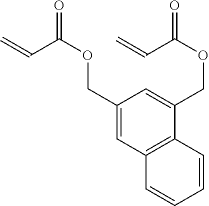 [SMILES: C=CC(=O)OCc1cc(COC(=O)C=C)c2ccccc2c1]

The blending ratio of the component (a) in the curable composition (A) is preferably 40 wt % or more and 99 wt % or less with respect to the sum of the component (a), a component (b) (to be described later), and a component (c) (to be described later), that is, the total mass of all the components except the solvent (d). The blending ratio is more preferably 50 wt % or more and 95 wt % or less, and further preferably 60 wt % or more and 90 wt % or less. When the blending ratio of the component (a) is 40 wt % or more, the mechanical strength of the cured film of the curable composition increases. Also, when the blending ratio of the component (a) is 99 wt % or less, it is possible to increase the blending ratios of the components (b) and (c), and obtain characteristics such as a high photopolymerization rate.

At least a part of the component (a) of the present disclosure, which may include a plurality of types of additive components, can be polymers having a polymerizable functional group. The polymer preferably contains at least a cyclic structure such as an aromatic structure, an aromatic heterocyclic structure, or an alicyclic structure. For example, the polymer preferably contains at least one of constituent units represented by formulas (1) to (6) below:

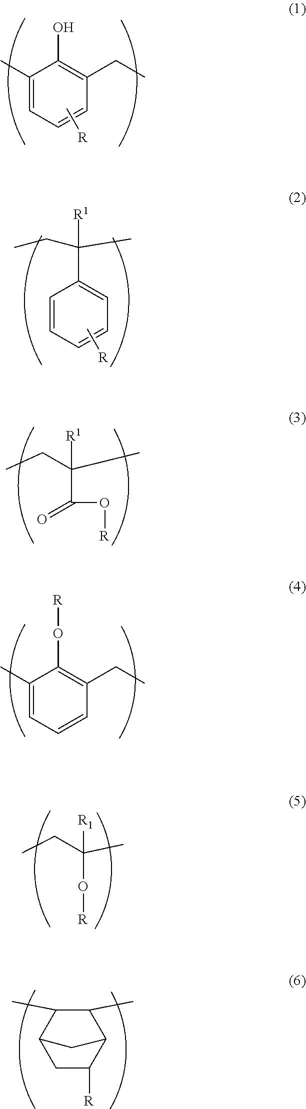

In the formulas (1) to (6), a substituent group R is a substituent group containing partial structures each independently containing an aromatic ring, and R1 is a hydrogen atom or a methyl group. In this specification, in constituent units represented by the formulas (1) to (6), a portion other than R is the main chain of a specific polymer. The formula weight of the substituent group R is 80 or more, preferably 100 or more, more preferably 130 or more, and further preferably 150 or more. The upper limit is practically 500 or less.

A polymer having a polymerizable functional group is normally a compound having a weight-average molecular weight of 500 or more. The weight-average molecular weight is preferably 1,000 or more, and more preferably 2,000 or more. The upper limit of the weight-average molecular weight is not particularly determined, but is preferably, for example, 50,000 or less. When the weight-average molecular weight is set at the above-described lower limit or more, it is possible to set the boiling point at 250° C. or more, and further improve the mechanical properties after curing. Also, when the weight-average molecular weight is set at the above-described upper limit or less, the solubility to the solvent increases, and the flowability of discretely arranged droplets is maintained because the viscosity is not too high. This makes it possible to further improve the flatness of the liquid film surface. Note that the weight-average molecular weight (Mw) in the present disclosure is a molecular weight measured by gel permeation chromatography (GPC).

Practical examples of the polymerizable functional group of the polymer are a (meth)acryloyl group, an epoxy group, an oxetane group, a methylol group, a methylol ether group, and a vinyl ether group. A (meth)acryloyl group is particularly favorable from the viewpoint of polymerization easiness.

When adding the polymer having the polymerizable functional group as at least a part of the component (a), the blending ratio can freely be set as long as the blending ratio falls within the range of the viscosity regulation to be described later. For example, the blending ratio of polymer to the total mass of all the components except for the solvent (d) is preferably 0.1 wt % or more and 60 wt % or less, more preferably 1 wt % or more and 50 wt % or less, and further preferably 10 wt % or more and 40 wt % or less. When the blending ratio of the polymer having the polymerizable functional group is set at 0.1 wt % or more, it is possible to improve the dry etching resistance, the heat resistance, the mechanical strength, and the low volatility. Also, when the blending ratio is set at 60 wt % or less, it is possible to make the blending ratio fall within the range of the upper limit regulation of the viscosity (to be described later).

### <Component (b): Photopolymerization Initiator>

The component (b) is a photopolymerization initiator. In this specification, the photopolymerization initiator is a compound that senses light having a predetermined wavelength and generates a polymerization factor (radical) described earlier. More specifically, the photopolymerization initiator is a polymerization initiator (radical generator) that generates a radical by light (infrared light, visible light, ultraviolet light, far-ultraviolet light, X-ray, a charged particle beam such as an electron beam, or radiation). The component (b) can be formed by only one type of a photopolymerization initiator, and can also be formed by a plurality of types of photopolymerization initiators.

Examples of the radical generator are as follows, but the radical generator is not limited to these examples.

2,4,5-triarylimidazole dimers that can have substituent groups, such as a 2-(o-chlorophenyl)-4,5-diphenylimidazole dimer, a 2-(o-chlorophenyl)-4,5-di(methoxyphenyl) imidazole dimer, a 2-(o-fluorophenyl)-4,5-diphenylimidazole dimer, and a 2-(o- or p-methoxyphenyl)-4,5-diphenylimidazole dimer; benzophenone derivatives such as benzophenone, N,N′-tetramethyl-4,4′-diaminobenzophenone (Michiler's ketone), N,N′-tetraethyl-4,4′-diaminobenzophenone, 4-methoxy-4′-dimethylaminobenzophenone, 4-chlorobenzophenone, 4,4′-dimethoxybenzophenone, and 4,4′-diaminobenzophenone; α-amino aromatic ketone derivatives such as 2-benzyl-2-dimethylamino-1-(4-morpholinophenyl)-butanone-1,2-methyl-1-[4-(methylthio)phenyl]-2-morpholino-propane-1-one; quinones such as 2-ethylanthraquinone, phenanthrenequinone, 2-t-butylanthraquinone, octamethylanthraquinone, 1,2-benzanthraquinone, 2,3-benzanthraquinone, 2-phenylanthraquinone, 2,3-diphenylamthraquinone, 1-chloroanthraquinone, 2-methylanthraquinone, 1,4-naphtoquinone, 9,10-phenanthraquinone, 2-methyl-1,4-naphtoquinone, and 2,3-dimethylanthraquinone; benzoin ether derivatives such as benzoin methyl ether, benzoin ethyl ether, and benzoin phenyl ether; benzoin derivatives such as benzoin, methyl benzoin, ethyl benzoin, and propyl benzoin; benzyl derivatives such as benzyldimethylketal; acridine derivatives such as 9-phenylacridine and 1,7-bis(9,9′-acrydinyl) heptane; N-phenylglycine derivatives such as N-phenylglycine; acetophenone derivatives such as acetophenone, 3-methylacetophenone, acetophenone benzylketal, 1-hydroxycylohexyl phenylketone, and 2,2-dimethoxy-2-phenyl acetophenone; thioxanthone derivatives such as thioxanthone, diethylthioxanthone, 2-isopropylthioxanthone, and 2-chlorothioxanthone; acylphosphine oxide derivatives such as 2,4,6-trimethylbenzoyldiphenylphosphine oxide, bis(2,4,6-trimethylbenzoyl)phenylphosphine oxide, and bis-(2,6-dimethoxybenzoyl)-2,4,4-trimethylpentylphosphine oxide; oxime ester derivatives such as 1,2-octanedione, 1-[4-(phenylthiol)-, 2-(O-benzoyloxime)], ethanone, 1-[9-ethyl-6-(2-methylbenzoyl)-9H-carbazole-3-yl]-, and 1-(O-acetyloxime); and xanthone, fluorenone, benzaldehyde, fluorene, anthraquinone, triphenylamine, carbazole, 1-(4-isopropylphenyl)-2-hydroxy-2-methylprapane-1-one, and 2-hydroxy-2-methyl-1-phenylpropane-1-one.

Examples of commercially available products of the above-described radical generators are as follows, but the products are not limited to these examples.

Irgacure 184, 369, 651, 500, 819, 907, 784, and 2959, CGI-1700, -1750, and -1850, CG24-61, Darocur 1116 and 1173, Lucirin® TPO, LR8893, and LR8970 (manufactured by BASF), and Ubecryl P36 (manufactured by UCB).

Of the above-described radical generators, the component (b) is preferably an acylphosphine oxide-based polymerization initiator. Note that of the above-described radical generators, the acylphosphine oxide-based polymerization initiators are as follows.

Acylphosphine oxide compounds such as 2,4,6-trimethylbenzoyl diphenylphosphine oxide, bis(2,4,6-trimethylbenzoyl)phenylphosphine oxide, and bis(2,6-dimethoxybenzoyl)-2,4,4-trimethylpentylphosphine oxide.

The blending ratio of the component (b) in the curable composition (A) is preferably 0.1 wt % or more and 50 wt % or less with respect to the sum of the component (a), the component (b), and a component (c) (to be described later), that is, the total mass of all the components except for the solvent (d). Also, the blending ratio of the component (b) in the curable composition (A) is more preferably 0.1 wt % or more and 20 wt % or less, and further preferably 1 wt % or more and 20 wt % or less with respect to the total mass of all the components except for the solvent (d). When the blending ratio of the component (b) is set at 0.1 wt % or more, the curing rate of the composition increases, so the reaction efficiency can be improved. Also, when the blending ratio of the component (b) is set at 50 wt % or less, a cured film having mechanical strength to some extent can be obtained.

### <Component (c): Nonpolymerizable Compound>

In addition to the components (a) and (b) described above, the curable composition (A) of the present disclosure can further contain a nonpolymerizable compound as the component (c) within a range that does not impair the effect of the present invention. An example of the component (c) is a compound that does not contain a polymerizable functional group such as a (meth)acryloyl group, and does not have the ability to sense light having a predetermined wavelength and generate the polymerization factor (radical) described previously. Examples of the nonpolymerizable compound are a sensitizer, a hydrogen donor, an internal mold release agent, an antioxidant, a polymer component, and other additives. The component (c) can contain a plurality of types of the above-described compounds.

The sensitizer is a compound that is properly added for the purpose of promoting the polymerization reaction and improving the reaction conversion rate. As the sensitizer, it is possible to use one type of a compound alone, or to use two or more types of compounds by mixing them.

An example of the sensitizer is a sensitizing dye. The sensitizing dye is a compound that is excited by absorbing light having a specific wavelength and has an interaction with a photopolymerization initiator as the component (b). The “interaction” herein mentioned is energy transfer or electron transfer from the sensitizing dye in the excited state to the photopolymerization initiator as the component (b). Practical examples of the sensitizing dye are as follows, but the sensitizing dye is not limited to these examples.

An anthracene derivative, an anthraquinone derivative, a pyrene derivative, a perylene derivative, a carbazole derivative, a benzophenone derivative, a thioxanthone derivative, a xanthone derivative, a coumarin derivative, a phenothiazine derivative, a camphorquinone derivative, an acridinic dye, a thiopyrylium salt-based dye, a merocyanine-based dye, a quinoline-based dye, a styryl quinoline-based dye, a ketocoumarin-based dye, a thioxanthene-based dye, a xanthene-based dye, an oxonol-based dye, a cyanine-based dye, a rhodamine-based dye, and a pyrylium salt-based dye.

The hydrogen donor is a compound that reacts with an initiation radical generated from the photopolymerization initiator as the component (b) or a radical at a polymerization growth end, and generates a radical having higher reactivity. The hydrogen donor is preferably added when the photopolymerization initiator as the component (b) is a photo-radical generator.

Practical examples of the hydrogen donor as described above are as follows, but the hydrogen donor is not limited to these examples.

Amine compounds such as n-butylamine, di-n-butylamine, tri-n-butylphosphine, allylthiourea, s-benzylisothiuronium-p-toluenesulfinate, triethylamine, diethylaminoethyl methacrylate, triethylenetetramine, 4,4′-bis(dialkylamino)benzophenone, N,N-dimethylamino ethylester benzoate, N,N-dimethylamino isoamylester benzoate, pentyl-4-dimethylamino benzoate, triethanolamine, and N-phenylglycine; and mercapto compounds such as 2-mercapto-N-phenylbenzoimidazole and mercapto propionate ester.

It is possible to use one type of a hydrogen donor alone, or to use two or more types of hydrogen donors by mixing them. The hydrogen donor can also have a function as a sensitizer.

An internal mold release agent can be added to the curable composition for the purpose of reducing the interface bonding force between a mold and the curable composition, that is, reducing the mold release force in a mold release step (to be described later). In this specification, “internal” means that the mold release agent is added to the curable composition in advance before a curable composition arranging step. As the internal mold release agent, it is possible to use surfactants such as a silicon-based surfactant, a fluorine-based surfactant, and a hydrocarbon-based surfactant. In the present disclosure, however, the addition amount of the fluorine-based surfactant is limited as will be described later. Note that the internal mold release agent according to the present disclosure is not polymerizable. It is possible to use one type of an internal mold release agent alone, or to use two or more types of internal mold release agents by mixing them.

The fluorine-based surfactant includes the following.

A polyalkylene oxide (for example, polyethylene oxide or polypropylene oxide) adduct of alcohol having a perfluoroalkyl group, and a polyalkylene oxide (for example, polyethylene oxide or polypropylene oxide) adduct of perfluoropolyether.

Note that the fluorine-based surfactant can have a hydroxyl group, an alkoxy group, an alkyl group, an amino group, or a thiol group in a portion (for example, a terminal group) of the molecular structure. An example is pentadecaethyleneglycol mono1H, 1H,2H,2H-perfluorooctylether.

It is also possible to use a commercially available product as the fluorine-based surfactant. Examples of the commercially available product of the fluorine-based surfactant are as follows.

MEGAFACE® F-444, TF-2066, TF-2067, and TF-2068, and DEO-15 (abbreviation) (manufactured by DIC); Fluorad FC-430 and FC-431 (manufactured by Sumitomo 3M); Surflon S-382 (manufactured by AGC); EFTOP EF-122A, 122B, 122C, EF-121, EF-126, EF-127, and MF-100 (manufactured by Tochem Products); PF-636, PF-6320, PF-656, and PF-6520 (manufactured by OMNOVA Solutions); UNIDYNE® DS-401, DS-403, and DS-451 (manufactured by DAIKIN); and FUTAGENT 250, 251, 222F, and 208G (manufactured by NEOS).

The internal mold release agent can also be a hydrocarbon-based surfactant. The hydrocarbon-based surfactant includes an alkyl alcohol polyalkylene oxide adduct obtained by adding alkylene oxide having a carbon number of 2 to 4 to alkyl alcohol having a carbon number of 1 to 50, and polyalkylene oxide.

Examples of the alkyl alcohol polyalkylene oxide adduct are as follows.

A methyl alcohol ethylene oxide adduct, a decyl alcohol ethylene oxide adduct, a lauryl alcohol ethylene oxide adduct, a cetyl alcohol ethylene oxide adduct, a stearyl alcohol ethylene oxide adduct, and a stearyl alcohol ethylene oxide/propylene oxide adduct.

Note that the terminal group of the alkyl alcohol polyalkylene oxide adduct is not limited to a hydroxyl group that can be manufactured by simply adding polyalkylene oxide to alkyl alcohol. This hydroxyl group can also be substituted by a polar functional group such as a carboxyl group, an amino group, a pyridyl group, a thiol group, or a silanol group, or by a hydrophobic group such as an alkyl group or an alkoxy group.

Examples of polyalkylene oxide are as follows.

Polyethylene glycol, polypropylene glycol, their mono or dimethyl ether, mono or dioctyl ether, mono or dinonyl ether, and mono or didecyl ether, monoadipate, monooleate, monostearate, and monosuccinate.

A commercially available product can also be used as the alkyl alcohol polyalkylene oxide adduct. Examples B of the commercially available product of the alkyl alcohol polyalkylene oxide adduct are as follows.

Polyoxyethylene methyl ether (a methyl alcohol ethylene oxide adduct) (BLAUNON MP-400, MP-550, and MP-1000) manufactured by AOKI OIL INDUSTRIAL, polyoxyethylene decyl ether (a decyl alcohol ethylene oxide adduct) (FINESURF D-1303, D-1305, D-1307, and D-1310) manufactured by AOKI OIL INDUSTRIAL, polyoxyethylene lauryl ether (a lauryl alcohol ethylene oxide adduct) (BLAUNON EL-1505) manufactured by AOKI OIL INDUSTRIAL, polyoxyethylene cetyl ether (a cetyl alcohol ethylene oxide adduct) (BLAUNON CH-305 and CH-310) manufactured by AOKI OIL INDUSTRIAL, polyoxyethylene stearyl ether (a stearyl alcohol ethylene oxide adduct) (BLAUNON SR-705, SR-707, SR-715, SR-720, SR-730, and SR-750) manufactured by AOKI OIL INDUSTRIAL, randomly polymerized polyoxyethylene polyoxypropylene stearyl ether (BLAUNON SA-50/50 1000R and SA-30/70 2000R) manufactured by AOKI OIL INDUSTRIAL, polyoxyethylene methyl ether (Pluriol® A760E) manufactured by BASF, and polyoxyethylene alkyl ether (EMULGEN series) manufactured by KAO.

A commercially available product can also be used as polyalkylene oxide. An example is an ethylene oxide/propylene oxide copolymer (Pluronic PE6400) manufactured by BASF.

The fluorine-based surfactant shows an excellent mold release force reducing effect and hence is effective as an internal mold release agent. The blending ratio of the component (c) in the curable composition (A) except for the fluorine-based surfactant is preferably 0 wt % or more and 50 wt % or less with respect to the sum of the components (a), (b), and (c), that is, the total mass of all the components except for the solvent (d). The blending ratio of the component (c) in the curable composition (A) except for the fluorine-based surfactant is more preferably 0.1 wt % or more and 50 wt % or less, and further preferably 0.1 wt % or more and 20 wt % or less with respect to the total mass of all the components except for the solvent (d). When the blending ratio of the component (c) except for the fluorine-based surfactant is set at 50 wt % or less, a cured film having mechanical strength to some extent can be obtained.

### <Component (d): Solvent>

The curable composition of the present disclosure contains a solvent having a boiling point of 80° C. or more and less than 250° C. at normal pressure as the component (d). The component (d) is a solvent that dissolves the components (a), (b), and (c). Examples are an alcohol-based solvent, a ketone-based solvent, an ether-based solvent, and a nitrogen-containing solvent. As the component (d), it is possible to use one type of a component alone, or to use two or more types of components by combining them. The boiling point at normal pressure of the component (d) is 80° C. or more, preferably 140° C. or more, and particularly preferably 150° C. or more. The boiling point at normal pressure of the component (d) is less than 250° C., and preferably 200° C. or less. If the boiling point of the component (d) at normal pressure is less than 80° C., volatilization progresses even during the arranging step, and stability of the step is impaired. Also, if the boiling point at normal pressure of the component (d) is 250° C. or more, it is possible that the volatilization of the solvent (d) is insufficient in the subsequent waiting step, so the component (d) remains in the cured film of the curable composition (A).

Examples of the alcohol-based solvent are as follows.

Monoalcohol-based solvents such as methanol, ethanol, n-propanol, iso-propanol, n-butanol, iso-butanol, sec-butanol, tert-butanol, n-pentanol, iso-pentanol, 2-methylbutanol, sec-pentanol, tert-pentanol, 3-methoxybutanol, n-hexanol, 2-methylpentanol, sec-hexanol, 2-ethylbutanol, sec-heptanol, 3-heptanol, n-octanol, 2-ethylhexanol, sec-octanol, n-nonyl alcohol, 2,6-dimethylheptanol-4, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethylcarbinol, diacetone alcohol, and cresol; and polyalcohol-based solvents such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol, and glycerin.

Examples of the ketone-based solvent are as follows.

Acetone, methylethylketone, methyl-n-propylketone, methyl-n-butyketone, diethylketone, methyl-iso-butylketone, methyl-n-pentylketone, ethyl-n-butylketone, methyl-n-hexylketone, di-iso-butylketone, trimethylnonanon, cyclohexanone, methylcyclohexanone, 2,4-pentanedione, acetonylacetone, diacetone alcohol, acetophenone, and fenthion.

Examples of the ether-based solvent are as follows.

Ethyl ether, iso-propyl ether, n-butyl ether, n-hexyl ether, 2-ethylhexyl ether, ethylene oxide, 1,2-propylene oxide, dioxolane, 4-methyldioxolane, dioxane, dimethyldioxane, 2-methoxyethanol, 2-ethoxyethanol, ethylene glycol diethyl ether, 2-n-butoxyethanol, 2-n-hexoxyethanol, 2-phenoxyethanol, 2-(2-ethylbutoxy) ethanol, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxy triglycol, tetraethylene glycol di-n-butyl ether, 1-n-butoxy-2-propanol, 1-phenoxy-2-propanol, propylene glycol monomethyl ether, propylene glycol monoethyl ether, propylene glycol monopropyl ether, dipropylene glycol monomethyl ether, dipropylene glycol monoethyl ether, dipropylene glycol monopropyl ether, tripropylene glycol monomethyl ether, tetrahydrofuran, and 2-methyltetrahydrofuran.

Examples of the ester-based solvent are as follows.

Diethyl carbonate, methyl acetate, ethyl acetate, amyl acetate, γ-butyrolactone, γ-valerolactone, n-propyl acetate, iso-propyl acetate, n-butyl acetate, iso-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxy triglycol acetate, ethyl propionate, n-butyl propionate, iso-amyl propionate, diethyl oxalate, di-n-butyl oxalate, methyl lactate, ethyl lactate, n-butyl lactate, n-amyl lactate, diethyl malonate, dimethyl phthalate, and diethyl phthalate.

Examples of the nitrogen-containing solvent are as follows.

N-methylformamide, N,N-dimethylformamide, N,N-diethylformamide, acetoamide, N-methylacetoamide, N,N-dimethylacetoamide, N-methylpropionamide, and N-methylpyrrolidone.

Of the above-described solvents, the ether-based solvent and the ester-based solvent are favorable. Note that an ether-based solvent and an ester-based solvent each having a glycol structure are more favorable from the viewpoint of good film formation properties.

Further favorable examples of the solvent are as follows.

Propylene glycol monomethyl ether, propylene glycol monoethyl ether, propylene glycol monopropyl ether, propylene glycol monomethyl ether acetate, propylene glycol monoethyl ether acetate, and propylene glycol monopropyl ether acetate.

A particularly favorable example is propylene glycol monomethyl ether acetate.

In the present disclosure, a favorable solvent is a solvent having at least one of an ester structure, a ketone structure, a hydroxyl group, and an ether structure. More specifically, a favorable solvent is one solvent or a solvent mixture selected from propylene glycol monomethyl ether acetate (boiling point=146° C.), propylene glycol monomethyl ether, cyclohexanone, 2-heptanone, Y-butyrolactone, and ethyl lactate.

In the present disclosure, a polymerizable compound having a boiling point of 80° C. or more and less than 250° C. at normal pressure is also usable as the component (d). Examples of the polymerizable compound having a boiling point of 80° C. or more and less than 250° C. at normal pressure are as follows.

Cyclohexyl acrylate (boiling point=198° C.), benzyl acrylate (boiling point=229° C.), isobornyl acrylate (boiling point=245° C.), tetrahydrofurfuryl acrylate (boiling point=202° C.), trimethylcyclohexyl acrylate (boiling point=232° C.), isooctyl acrylate (217° C.), n-octyl acrylate (boiling point=228° C.), ethoxyethoxyethyl acrylate (boiling point=230° C.), divinylbenzene (boiling point=193° C.), 1,3-diisopropenylbenzene (boiling point=218° C.), styrene (boiling point=145° C.), and α-methylstyrene (boiling point=165° C.).

In the arranging step of the present disclosure, when the whole of the curable composition (A) is 100 vol %, the content of the solvent (d) in a case where an inkjet method is used is 0 vol % or more and 95 vol % or less. The content is preferably 70 vol % or more and 85 vol % or less, and further preferably 70 vol % or more and 80 vol % or less. If the content of the solvent (d) is 70 vol % or more, the droplets bond to each other in the waiting step, and a practically continuous liquid film can be obtained. On the other hand, if the content of the solvent (d) is larger than 95 vol %, no thick film can be obtained after the solvent (d) volatilized even when droplets are closely dropped by an inkjet method.

When the whole of the curable composition (A) is 100 vol %, the content of the solvent (d) in a case where a spin coating method is used in the arranging step of the present disclosure is 1 vol % or more and 99.9 vol % or less. The content is preferably 10 vol % or more and 99.9 vol % or less, further preferably 80 vol % or more and 99.9 vol % or less, and particularly preferably 90 vol % or more and 99.9 vol % or less. An appropriate content is determined based on the control range of the rotation speed of the spin coating apparatus, and the desired value of the film thickness.

### <Temperature When Blending Curable Composition>

When preparing the curable composition (A) of the present disclosure, at least the components (a), (b), and (d) are mixed and dissolved under a predetermined temperature condition. More specifically, the predetermined temperature condition is 0° C. or more and 100° C. or less. Note that the same applies to a case in which the curable composition (A) contains the component (c).

### <Viscosity of Curable Component>

The curable composition (A) of the present disclosure is a liquid. This is so because droplets of the curable composition (A) are arranged on a substrate by an inkjet method or a spin coating method in an arranging step (to be described later).

In the arranging step of the present disclosure, the viscosity of the curable composition (A) at 23° C. in a case where the inkjet method is used is 2 mPa·s or more and 60 mPa·s or less in a state in which the solvent (d) is contained. The viscosity is preferably 5 mPa·s or more and 30 mPa·s or less, and more preferably 5 mPa·s or more and 15 mPa·s or less. If the viscosity of the curable composition (A) is smaller than 2 mPa·s, the discharge property of droplets by an inkjet method becomes unstable. Also, if the viscosity of the curable composition (A) is larger than 60 mPa·s, it is impossible to form droplets having a volume of about 1.0 to 3.0 pL favorable in the present disclosure.

In the arranging step of the present disclosure, the viscosity of the curable composition (A) in a case where the spin coating method is used is 1 mPa·s or more and 100 mPa·s or less.

The viscosity in a state in which the solvent (d) volatilized from the curable composition (A), that is, the viscosity of a mixture of components except for the solvent (d) of the curable composition (A) at 23° C. is 1 mPa·s or more and 10,000 mPa·s or less. The viscosity is preferably 30 mPa·s or more and 2,000 mPa·s or less, more preferably 120 mPa·s or more and 1,000 mPa·s or less, and further preferably 200 mPa·s or more and 500 mPa·s or less. When the viscosity of the components except for the solvent (d) of the curable composition (A) is set to 1,000 mPa·s or less, spreading and filling are rapidly completed when bringing the curable composition (A) into contact with a mold. Accordingly, the use of the curable composition (A) of the present disclosure makes it possible to perform an imprinting process at high throughput, and suppress pattern defects caused by insufficient filling. Also, when the viscosity of components except for the solvent (d) of the curable composition (A) is set to 1 mPa·s or more, it is possible to prevent an unnecessary flow of droplets of the curable composition (A) after the solvent (d) volatilized. Furthermore, when bringing the curable composition (A) into contact with a mold, the curable composition (A) does not easily flow out from the end portions of the mold.

### <Surface Tension of Curable Composition>

The surface tension of the curable composition (A) of the present disclosure is as follows. The surface tension at 23° C. of the composition containing the components except for the solvent (component (d)) is preferably 5 mN/m or more and 70 mN/m or less. The surface tension at 23° C. of the composition containing the components except for the solvent (component (d)) is more preferably 7 mN/m or more and 50 mN/m or less, and further preferably 10 mN/m or more and 40 mN/m or less. Note that when the surface tension is high, for example, 5 mN/m or more, the capillarity strongly acts, so filling (spreading and filling) is complete within a short time period when the curable composition (A) and a mold are brought into contact with each other. Also, when the surface tension is 70 mN/m or less, a cured film obtained by curing the curable composition has surface smoothness.

### <Contact Angle of Curable Composition>

The contact angle of the curable composition (A) of the present disclosure is as follows. That is, the contact angle of the composition containing the components except for the solvent (component (d)) is preferably 0° or more and 90° or less and particularly preferably 0° or more and 10° or less with respect to both the surface of a substrate and the surface of a mold. If the contact angle is larger than 90°, the capillarity acts in a negative direction (a direction in which the contact interface between the mold and the curable composition is shrunk) inside a pattern of the mold or in a gap between the substrate and the mold, and this may make filling impossible. When the contact angle is small, the capillarity strongly acts, and the filling rate increases.

### <Impurities Mixed in Curable Composition>

The curable composition (A) of the present disclosure preferably contains impurities as little as possible. Note that impurities mean components other than the components (a), (b), (c), and (d) described above. Therefore, the curable composition (A) of the present disclosure is favorably a composition obtained through a refining step. A refining step like this is preferably filtration using a filter.

As this filtration using a filter, it is favorable to mix the components (a), (b), and (c) described above, and filtrate the mixture by using, for example, a filter having a pore diameter of 0.001 μm or more and 5.0 μm or less. When performing filtration using a filter, is it further favorable to perform the filtration in multiple stages, or to repetitively perform the filtration a plurality of times (cycle filtration). It is also possible to re-filtrate a liquid once filtrated through a filter, or perform filtration by using filters having different pore diameters. Examples of the filter for use in filtration are filters made of, for example, a polyethylene resin, a polypropylene resin, a fluorine resin, and a nylon resin, but the filter is not particularly limited. Impurities such as particles mixed in the curable composition can be removed through the refining step as described above. Consequently, it is possible to prevent impurities mixed in the curable composition from causing pattern defects by forming unexpected unevenness on a cured film obtained after the curable composition is cured.

Note that when using the curable composition of the present disclosure in order to fabricate a semiconductor integrated circuit, it is favorable to avoid mixing of impurities (metal impurities) containing metal atoms in the curable composition as much as possible so as not to obstruct the operation of a product. The concentration of the metal impurities contained in the curable composition is preferably 10 ppm or less, and more preferably 100 ppb or less.

### [Substrate]

In this specification, a member on which the curable composition (A) is arranged is explained as a substrate.

This substrate is a processing target substrate, and a silicon wafer is normally used. The substrate can have a processing target layer on the surface. On the substrate, another layer can also be formed below the processing target layer. When a quartz substrate is used as the substrate, a replica (replica mold) of a mold for imprinting can be manufactured. However, the substrate is not limited to a silicon wafer or a quartz substrate. The substrate can freely be selected from those known as semiconductor device substrates such as aluminum, a titanium-tungsten alloy, an aluminum-silicon alloy, an aluminum-copper-silicon alloy, silicon oxide, and silicon nitride. The processing target layer on the uppermost surface of the substrate may be an insulating film containing at least silicon atoms. Note that the processing target layer on the uppermost surface of the substrate is preferably treated by a surface treatment such as a silane coupling treatment, a silazane treatment, or deposition of an organic thin film, thereby improving the adhesion to the curable composition (A). As a practical example of the organic thin film to be deposited as the surface treatment, an adhesive layer described in PTL 4 can be used.

### [Pattern Forming Method]

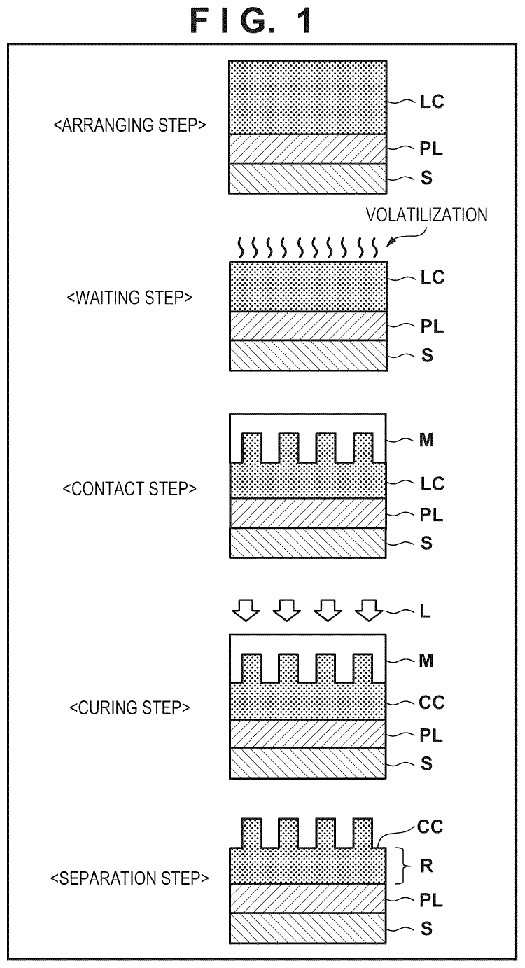

The pattern forming method of the present disclosure will be explained with reference to FIG. 1. The cured film formed by the present disclosure is preferably a film having a pattern with a size of 1 nm or more and 10 mm or less, and more preferably a film having a pattern with a size of 10 nm or more and 100 μm or less. The pattern forming method of the present disclosure forms a film of a curable composition in a space between a mold and a substrate by using a photoimprint method. However, the curable composition can also be cured by another energy (for example, heat or an electromagnetic wave).

The pattern forming method of the present disclosure will be explained below. The pattern forming method of the present disclosure can include, for example, an arranging step, a waiting step, a contact step, a curing step, and a separation step. The arranging step is a step of arranging a liquid film of the curable composition (A) on a substrate. The waiting step is a step of waiting until the component (d) solvent of the curable composition (A) volatilizes. The contact step is a step of bringing the curable composition (A) and a mold in contact with each other. The curing step is a step of curing the curable composition (A). The separation step is a step of separating the mold from the cured film of the curable composition (A). The waiting step is performed after the arranging step, the contact step is performed after the waiting step, the curing step is performed after the contact step, and the separation step is performed after the curing step.

The pattern forming method of the present disclosure further includes an inversion layer forming step, a surplus inversion layer removing step, and a residual film etching step. The inversion layer forming step is a step of forming an inversion layer on the cured film of the curable composition (A). The surplus inversion layer removing step is a step of removing the inversion layer formed on the upper portion of the convex portion of the cured film of the curable composition (A). The residual film etching step is a step of removing the residual film of the cured film of the curable composition (A) using the inversion layer remaining the concave portion of the cured film of the curable composition (A) as a mask. The surplus inversion layer removing step is performed after the inversion layer forming step, and the residual film etching step is performed after the surplus inversion layer removing step.

### <Arranging Step>

As schematically shown in FIG. 1, a processing target layer PL is formed on the uppermost layer of a substrate S. In the arranging step, a liquid film LC of the curable composition (A) is arranged on the processing target layer PL. As an arranging method of arranging the liquid film of the curable composition (A) on the substrate, an inkjet method or a spin coating method is preferably used.

In a case where the inkjet method is used, it is favorable to arrange the droplets of the curable composition (A) densely on a region of the substrate, which faces a region in which concave portions forming a pattern on a mold densely exist. On the other hand, it is favorable to arrange the droplets of the curable composition (A) sparsely on a region of the substrate, which faces a region in which concave portions forming a pattern on a mold sparsely exist. Consequently, a film (residual film) of the curable composition (A) formed on the substrate is controlled to have a uniform thickness regardless of the sparsity and density of the pattern of the mold. When discretely arranging the droplet of the curable composition (A) using the inkjet method, it is preferable that all the droplets bond to each other to form a practically continuous liquid film in the waiting step to be described later. In this case, since a spread process is omitted in the subsequent contact step, the time needed for the contact step is short.

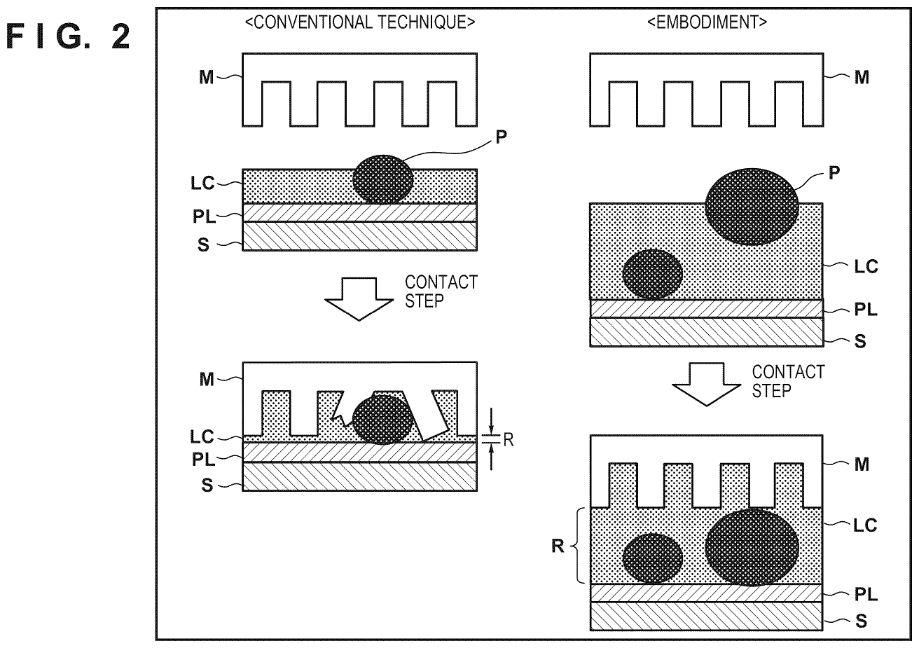

In the present disclosure, the amount of the curable composition (A) arranged on the substrate is adjusted such that the thickness of the residual film formed in the contact step is 1 time or more and 20 times or less the depth of the mold pattern. The amount is preferably 1 time or more and 6 times or less, further preferably 1 time or more and 4 times or less, and particularly preferably 2 time or more and 4 times or less. For example, if the depth of the mold pattern is 50 nm, the residual film thickness (the thickness of the residual film sandwiched between the substrate and the most projecting portion of the unevenness of the mold) is 50 nm or more and 1,000 nm or less. The residual film thickness is preferably 50 nm or more and 300 nm or less, further preferably 50 nm or more and 200 nm or less, and particularly preferably 100 nm or more and 200 nm or less. The thicker the residual film thickness is, the lower the possibility of breakage of the mold pattern by a foreign substance that can exist between the mold and the substrate is. FIG. 2 schematically shows the breaking behavior of a concave-convex pattern of a mold M by a foreign substance P sandwiched between the mold M and the substrate S. In the conventional technique, if the foreign substance P larger than the thickness of a residual film R is sandwiched, the concave-convex pattern of the mold M may be broken. On the other hand, in the present disclosure, the residual film R is thicker than in the conventional technique. Hence, even if a larger foreign substance exists, the foreign substance is buried in the residual film, and the concave-convex pattern is not broken. However, if the residual film is too thick, it may be difficult to expose the substrate surface in the residual film etching step to be described later.

Also, the height difference of the unevenness of the mold is equal to or less than the thickness of the residual film. In the present disclosure, since the residual film is thick, the allowance to the unevenness height difference on the substrate surface is high. For example, if the residual film thickness is 20 nm in the conventional technique, the substrate is preferably planarized such that the unevenness height difference is less than 20 nm. On the other hand, if the residual film thickness is 200 nm in the present disclosure, the substrate is allowed to have an unevenness height difference less than 20 nm.

### <Waiting Step>

Referring back to FIG. 1, in the present disclosure, a waiting step of volatilizing the component (d) that is the solvent is provided after the arranging step and before the contact step. If the curable composition (A) does not contain the component (d), the waiting step can be omitted. If the total weight of the components other than the component (d) is 100 vol %, the remaining amount of the component (d) in a liquid film F after the waiting step is preferably 10 vol % or less. If the remaining amount of the component (d) is larger than 10 vol %, the mechanical property of the cured film may be low.

The waiting step is a step of waiting for a predetermined time before the contact step is started after the arranging step. The predetermined time is, for example, 0.1 sec to 600 sec, and preferably 10 sec to 300 sec. If the inkjet method is used in the arranging step, it is preferable to wait until the discretely arranged droplets of the curable composition (A) bond to each other. If the waiting step is shorter than 0.1 sec, volatilization of the component (d) may be insufficient. If the waiting step exceeds 600 sec, productivity is low.

In the waiting step, it is possible to perform a baking step of heating the substrate and the curable composition (A), or ventilate the atmospheric gas around the substrate, for the purpose of accelerating the volatilization of the solvent (d). The baking step is performed at, for example, 30° C. or more and 200° C. or less, preferably 80° C. or more and 150° C. or less, and particularly preferably 80° C. or more and 110° C. or less. The heating time can be 10 sec or more and 600 sec or less. The baking step can be performed by using a known heater such as a hotplate or an oven.

If the solvent (d) is volatilized in the waiting step, a liquid film formed by the components (a), (b), and (c) remains on the substrate. The average film thickness of the liquid film from which the solvent (d) is volatilized (removed) is smaller than that of the liquid film immediately after the arranging step by an amount of volatilization of the solvent (d).

### <Contact Step>

In the contact step, as schematically shown in FIG. 1, the liquid film LC of the curable composition (A) from which the solvent (d) is removed is brought into contact with the mold M. The contact step includes a step of a changing a state in which the curable composition (A) and the mold M are not in contact with each other to a state in which they are in contact with each other, and a step of maintaining the state in which they are in contact with each other. As a consequence, the liquid of the curable composition (A) is filled in the concave portions of fine patterns on the surface of the mold M, and the liquid forms a liquid film filled in the fine patterns of the mold.

The contact step is preferably 0.1 sec or more and 3 sec or less, and particularly preferably 0.1 sec or more and 1 sec or less. If the contact step is shorter than 0.1 sec, spreading and filling become insufficient, so many defects called incomplete filling defects tend to occur. If the contact step is longer than 3 sec, productivity is low.

When the curing step includes a photoirradiation step, a mold made of a light-transmitting material is used as the mold by taking this into consideration. Favorable practical examples of the type of the material forming the mold are glass, quartz, PMMA, a photo-transparent resin such as a polycarbonate resin, a transparent metal deposition film, a soft film such as polydimethylsiloxane, a photo-cured film, and a metal film. Note that when using the photo-transparent resin as the material forming the mold, a resin that does not dissolve in components contained in a curable composition is selected. Quartz is particularly preferable as the material forming the mold because the thermal expansion coefficient is small and pattern distortion is small.

A pattern formed on the surface of the mold has a height of, for example, 4 nm or more and 200 nm or less. As the pattern height of the mold decreases, it becomes possible to decrease the force of releasing the mold from the cured film of the curable composition, that is, the mold release force in the separation step, and this makes it possible to decrease the number of mold release defects remaining in the mold because the pattern of the curable composition is torn off. Also, in some cases, the pattern of the curable composition elastically deforms due to the impact when the mold is released, and adjacent pattern elements come in contact with each other and adhere to each other or break each other. Note that to avoid these inconveniences, it is advantageous to make the height of pattern elements be about twice or less the width of the pattern elements (make the aspect ratio be 2 or less). On the other hand, if the height of pattern elements is too small, the processing accuracy of the processing target layer on the substrate decreases.

A surface treatment can also be performed on the mold before performing the contact step, in order to improve the detachability of the mold with respect to the curable composition (A). An example of this surface treatment is to form a mold release agent layer by coating the surface of the mold with a mold release agent. Examples of the mold release agent to be applied on the surface of the mold are a silicon-based mold release agent, a fluorine-based mold release agent, a hydrocarbon-based mold release agent, a polyethylene-based mold release agent, a polypropylene-based mold release agent, a paraffine-based mold release agent, a montane-based mold release agent, and a carnauba-based mold release agent. It is also possible to suitably use a commercially available coating-type mold release agent such as Optool® DSX manufactured by Daikin. Note that it is possible to use one type of a mold release agent alone, or use two or more types of mold release agents together. Of the mold release agents described above, fluorine-based and hydrocarbon-based mold release agents are particularly favorable.

In the contact step, the pressure to be applied to the curable composition (A) when bringing the mold into contact with the curable composition (A) is not particularly limited, and is, for example, 0 MPa or more and 100 MPa or less. Note that when bringing the mold 106 into contact with the curable composition (A), the pressure to be applied to the curable composition (A) is preferably 0 MPa or more and 50 MPa or less, more preferably 0 MPa or more and 30 MPa or less, and further preferably 0 MPa or more and 20 MPa or less.

The contact step can be performed in any of a normal air atmosphere, a reduced-pressure atmosphere, and an inert-gas atmosphere. However, the reduced-pressure atmosphere or the inert-gas atmosphere is favorable because it is possible to prevent the influence of oxygen or water on the curing reaction. Practical examples of an inert gas to be used when performing the contact step in the inert-gas atmosphere are nitrogen, carbon dioxide, helium, argon, various freon gases, and gas mixtures thereof. When performing the contact step in a specific gas atmosphere including a normal air atmosphere, a favorable pressure is 0.0001 atm or more and 10 atm or less.

### <Curing Step>

In the curing step as schematically shown in FIG. 1, the curable composition (A) is cured by being irradiated with irradiation light L as curing energy, thereby forming a cured film CC. In the curing step, for example, the curable composition (A) is irradiated with the irradiation light L through the mold M. More specifically, the curable composition (A) filled in the fine pattern of the mold M is irradiated with the irradiation light through the mold M. Consequently, the curable composition (A) filled in the fine pattern of the mold M is cured and forms the cured film CC having the pattern.

The irradiation light is selected in accordance with the sensitivity wavelength of the curable composition (A). More specifically, the irradiation light is properly selected from ultraviolet light, X-ray, and an electron beam each having a wavelength of 150 nm or more and 400 nm or less. Note that the irradiation light is particularly preferably ultraviolet light. This is so because many compounds commercially available as curing assistants have sensitivity to ultraviolet light. Examples of a light source that emits ultraviolet light are a high-pressure mercury lamp, an ultrahigh-pressure mercury lamp, a low-pressure mercury lamp, a Deep-UV lamp, a carbon arc lamp, a chemical lamp, a metal halide lamp, a xenon lamp, a KrF excimer laser, an ArF excimer laser, and an F₂ laser. Note that the ultrahigh-pressure mercury lamp is particularly favorable as the light source for emitting ultraviolet light. It is possible to use one light source or a plurality of light sources. Light can be emitted to the entire region of the curable composition (A) filled in the fine pattern of the mold, or to only a partial region thereof (by limiting the region). It is also possible to intermittently emit light to the entire region of the substrate a plurality of times, or to continuously emit light to the entire region of the substrate. Furthermore, a first region of the substrate can be irradiated with light in a second irradiation process, and a second region different from the first region of the substrate can be irradiated with light in the second irradiation process.

### <Separation Step>

In the separation step as schematically shown in FIG. 1, the mold M is released from the cured film CC. When the mold M is released from the cured film CC having the pattern, the cured film CC having a pattern formed by inverting the fine pattern of the mold M is obtained in an independent state. In this state, a cured film remains in concave portions of the cured film CC having the pattern. This film is called the residual film R.

A method of releasing the mold from the cured film having the pattern can be any method provided that the method does not physically break a part of the cured film having the pattern during the release, and various conditions and the like are not particularly limited. For example, it is possible to fix the substrate and move the mold away from the substrate. It is also possible to fix the mold and move the substrate away from the mold. Furthermore, the mold can be released from the cured film having the pattern by moving both the mold and the substrate in exactly opposite directions.

### <Repetition>

A series of steps (a fabrication process) having the above-described steps from the arranging step to the separation step in this order make it possible to obtain a cured film having a desired concave-convex pattern shape (a pattern shape conforming to the concave-convex shape of the mold) in a desired position.

In the pattern forming method of the present disclosure, a repetition unit (shot) from the arranging step to the separation step, or from the contact step to the separation step, can repetitively be performed a plurality of times on the same substrate. Thus, the cured film having a plurality of desired patterns in desired positions of the substrate can be obtained.

In the present disclosure, an inversion process to be described later in detail is executed to process the processing target layer on the substrate using the cured film having the pattern shape, which is obtained by the arranging step to the separation step.

### <Inversion Layer Forming Step>

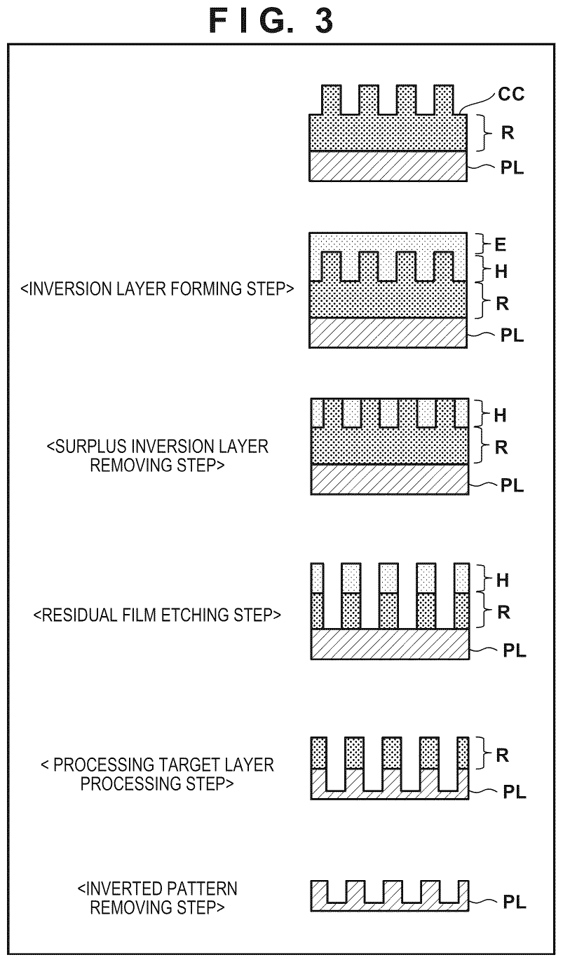

As shown in FIG. 3, an inversion layer H is formed on the cured film CC having the pattern shape formed by the arranging step to the separation step to bury the concave portions of the pattern.

The material of the inversion layer can be selected from silicon-based materials such as SiO₂ and SiN, organic materials containing silicon, metal oxide film materials such as TiO₂ and Al₂O₃, and general metal materials.

For example, as a method of forming an inversion layer using SiO₂, spin coating of a Spin-On-Glass (SOG) material, or plasma CVD deposition by TEOS (Tetra Ethyl Ortho Silicate) can be used. Examples of commercially available SOG are T-111 manufactured by Honeywell and OCD T-12 manufactured by TOKYO OHKA KOGYO, but the material is not limited to these.

### <Surplus Inversion Layer Removing Step>

In the surplus inversion layer removing step, an inversion layer is formed even on the upper portions of the convex portions of the cured film CC having the pattern shape (such a part of the inversion layer will be referred to as a “surplus inversion layer” hereinafter). A surplus inversion layer E needs to be removed until the upper portions of the convex portions of the cured film CC having the pattern shape are exposed, as shown in FIG. 3. In the surplus inversion layer removing step, in a state in which the inversion layer is buried in the concave portions of unevenness formed on the cured film, the upper layer portion of the inversion layer is removed to expose the top surfaces of the convex portions of unevenness formed on the cured film.

A detailed method for removing the surplus inversion layer E is not particularly limited, and a known method, for example, dry etching can be used. For the dry etching, a known dry etching apparatus can be used. A source gas at the time of dry etching is appropriately selected depending on the element composition of the inversion layer. For example, as the source gas at the time of dry etching, the following fluorocarbon-based gases can be used.

CF₄, CHF₄, C₂F₆, C₃F₈, C₄F₈, C₅F₈, C₄F₆, CCl₂F₂, and CBrF₃.

Alternatively, as the source gas at the time of dry etching, the following halogen-based gases can be used.

CCl₄, BCl₃, PCl₃, SF₆, and Cl₂.

Note that these gases can be used in mixture.

### <Residual Film Etching Step>

Using the inversion layer H buried in the pattern concave portions and remaining as a processing mask, the cured film CC having the pattern shape is etched with respect to the portions exposed by the surplus inversion layer removing step as a start point. Etching is continued until the surface of the processing target layer PL on the substrate is exposed. By this step, a pattern (to be referred to as an inverted pattern hereinafter) in which the unevenness of the cured film CC of the curable composition (A) is inverted is formed as shown in FIG. 1. A detailed method of etching is not particularly limited, and a conventionally known method, for example, dry etching can be used. For the dry etching, a conventionally known dry etching apparatus can be used. A source gas at the time of dry etching is appropriately selected depending on the element composition of the resist layer. A gas containing oxygen atoms, such as O₂, CO, or CO₂, an inert gas such as He, N₂, or Ar, or a gas such as N₂, H₂, or NH₃ can be used. Note that these gases can be used in mixture.

### <Processing Target Layer Processing Step>

Furthermore, in the present disclosure, as shown in FIG. 3, using the inverted pattern as a mask, the processing target layer PL on the substrate is etched, thereby obtaining a processing target layer having the pattern shape. Using the inverted pattern as a processing mask, ion implantation may be performed for the processing target layer. Etching of the processing target layer may be executed under the same conditions as the etching of the surplus inversion layer described above, or may be executed under different conditions suitable for etching of the processing target layer. After processing of the processing target layer, the inverted pattern serving as the processing mask may be removed.

### [Article Manufacturing Method]

The inverted pattern formed by the pattern forming method according to the present disclosure can directly be used as the constituent member of at least some of various kinds of articles. Also, the inverted pattern is temporarily be used as a processing mask in etching or ion implantation for the processing target layer on the substrate. In the processing step of the processing target layer on the substrate, after etching or ion implantation is performed for the processing target layer, the inverted pattern serving as the processing mask is removed. Various kinds of articles can thus be manufactured.

An article is, for example, an electric circuit element, an optical element, MEMS, a recording element, a sensor, or a mold. Examples of the electric circuit element are volatile or nonvolatile semiconductor memories such as a DRAM, an SRAM, a flash memory, and an MRAM, and semiconductor elements such as an LSI, a CCD, an image sensor, and an FPGA. If the processing target layer is an insulating layer, it can be used as an interlayer dielectric film included in the above-described semiconductor memory or semiconductor element.

The processing target layer having the pattern shape obtained by the arranging step to the processing target layer etching step can be used as an optical member (or as one member of an optical member) such as a diffraction grating or a polarizing plate. In a case like this, an optical element including at least a substrate, and a processing target layer having a pattern shape on the substrate can be obtained. Examples of the optical element are a micro lens, a light guide body, a waveguide, an antireflection film, a diffraction grating, a polarizer, a color filter, a light-emitting element, a display, and a solar battery.

Examples of the MEMS are a DMD, a microchannel, and an electromechanical transducer. Examples of the recording element are optical disks such as a CD and a DVD, a magnetic disk, a magneto-optical disk, and a magnetic head. Examples of the sensor are a magnetic sensor, a photosensor, and a gyro sensor. An example of the mold is a mold for imprinting.

### Examples

More practical examples will be explained in order to supplement the above-described embodiments. The present invention will be described below in more detail using the examples, but the technical scope of the present invention is not limited to the examples to be described below.

### <Estimate of Possibility of Breakage of Mold Pattern>

The number of particles remaining in a curable composition (A) in a liquid form filtrated using a polyethylene resin filter and a nylon resin filter was measured using a liquid-borne particle counter KS-19F available from Rion Co., LTD. The number of particles having a diameter of 70 nm or more was 117 pieces/ml, and the number of particles having a diameter of 200 nm or more was 3 pieces/ml. The larger the diameter of the particle was, the smaller the number of particles was. According to the measurement result, it can be said that the probability that the mold is broken by sandwiching particles remaining in the curable composition (A) in a case where the residual film thickness is 200 nm is 1/39 or less as compared to a case where the residual film thickness is 70 nm, and the probability of breakage of the mold lowers as the residual film thickness increases.

### <Dry Etching Resistance: Inkjet Method>

Curable compositions (AC1), (AC2), and (A1) to (A3) shown in Table 1 are adjusted in accordance with the following procedure. Components (a) to (c) shown in Table 1 are mixed. Next, a component (d) is added such that the content of the component (d) is 80 vol % with respect to the content (20 vol %) of the mixture of the components (a) to (c), thereby obtaining the curable composition (A) having a total content of 100 vol %.

Abbreviations in Tables 1 to 4 are as follows.
a1: 2-phenylphenoxyethyl acrylate
a2: tricyclodecanedimethanol diacrylate
a3: 3-phenoxybenzyl acrylate
a4: BPh43DA
a5: Na13MDA
b1: bis(2,4,6-trimethylbenzoyl)phenylphosphine oxide
d1: cyclohexanone
d2: benzyl acrylate

TABLE 1

| | Comparative | Comparative | | | |
|---|---|---|---|---|---|
| | Example 1 | Example 2 | Example | Example | Example |
| | (AC1) | (AC2) | 1 (A1) | 2 (A2) | 3 (A3) |
| Component | a1/0 | a1/30 | a1/40 | a1/70 | a1/100 |
| (a)/parts by | a2/100 | a2/70 | a2/60 | a2/30 | a2/0 |
| weight | | | | | |
| Component | b1/5 | ← | ← | ← | ← |
| (b)/parts by | | | | | |
| weight | | | | | |
| Component | none | ← | ← | ← | ← |
| (c)/parts by | | | | | |
| weight | | | | | |
| Total | 20 | ← | ← | ← | ← |
| vol % of | | | | | |
| components | | | | | |
| (a) to (c) | | | | | |
| Component | d1/80 | ← | ← | ← | ← |
| (d)/vol % | | | | | |
| OP | 3.29 | 3.05 | 2.98 | 2.77 | 2.57 |
| Processing | x | x | ○ | ○ | ○ |
| resistance | | | | | |

Spin on glass (SOG, T-111 manufactured by Honeywell) is deposited as a processing target layer having a thickness of 300 nm on a silicon substrate, and an adhesion layer described in PTL 4 is deposited as an adhesion layer having a thickness of 5 nm on the surface of the T-111 layer. For the curable compositions (AC1), (AC2), and (A1) to (A3) shown in Table 1, the arranging step to the separation step were executed. The pattern height of the mold, that is, the thickness of the inversion layer is set to 50 nm, and the residual film thickness is set to 200 nm. The inkjet method is used in the arranging step, and in the waiting step, the structure is let stand for 10 min at room temperature.

Next, the inversion layer forming step to the processing target layer processing step are executed for the cured films of the curable compositions (AC1), (AC2), and (A1) to (A3). As the inversion layer, T-111 manufactured by Honeywell is used, like the processing target layer. In the surplus inversion layer removing step and the residual film etching step, a high-density plasma etching apparatus NE-550 manufactured by ULVAC is used. These steps are executed using CF₄/CHF₃ mixed gas plasma and O₂/Ar mixed gas plasma, respectively.

A case where the T-111 layer that is the processing target layer can be processed until the silicon substrate surface is exposed in the processing target layer processing step is indicated by o, and a case where a failure such as disappearance of the cured film before the substrate surface is exposed occurs is indicated by x in Table 1.

The result shows that, in the inversion process of the present disclosure using a curable composition having an OP of 3.00 or less, the same processing performance as a conventional inversion process using a spin-on-carbon (SOC) layer can be obtained.

### <Dry Etching Resistance: Spin Coating Method>

Curable compositions (AC3), (AC4), and (A4) to (A6) shown in Table 2 are adjusted in accordance with the following procedure. Components (a) to (c) shown in Table 2 are mixed. Next, a component (d) is added such that the content of the component (d) is 90 vol % with respect to the content (10 vol %) of the mixture of the components (a) to (c), thereby obtaining the curable composition (A) having a total content of 100 vol %.

TABLE 2

| | Comparative | Comparative | | | |
|---|---|---|---|---|---|
| | Example 3 | Example 4 | Example | Example | Example |
| | (AC3) | (AC4) | 4 (A4) | 5 (A5) | 6 (A6) |
| Component | a1/0 | a1/30 | a1/40 | a1/70 | a1/100 |
| (a)/parts by | a2/100 | a2/70 | a2/60 | a2/30 | a2/0 |
| weight | | | | | |
| Component | b1/5 | ← | ← | ← | ← |
| (b)/parts by | | | | | |
| weight | | | | | |
| Component | none | ← | ← | ← | ← |
| (c)/parts by | | | | | |
| weight | | | | | |
| Total | 10 | ← | ← | ← | ← |
| vol % of | | | | | |
| components | | | | | |
| (a) to (c) | | | | | |
| Component | d1/90 | ← | ← | ← | ← |
| (d)/vol % | | | | | |
| OP | 3.29 | 3.05 | 2.98 | 2.77 | 2.57 |
| Processing | × | × | ○ | ○ | ○ |
| resistance | | | | | |

Spin on glass (SOG, T-111 manufactured by Honeywell) is deposited as a processing target layer having a thickness of 300 nm on a silicon substrate, and an adhesion layer described in PTL 4 is deposited as an adhesion layer having a thickness of 5 nm on the surface of the T-111 layer. For the curable compositions (AC3), (AC4), and (A4) to (A6) shown in Table 2, the arranging step to the separation step are executed on the substrate. The pattern height of the mold, that is, the thickness of the inversion layer is set to 50 nm, and the residual film thickness is set to 200 nm. The spin coating method is used in the arranging step, and in the waiting step, the structure is let stand for 10 min at room temperature.

Next, the inversion layer forming step to the processing target layer processing step are executed for the cured films of the curable compositions (AC3), (AC4), and (A4) to (A6). As the inversion layer, T-111 manufactured by Honeywell is used, like the processing target layer. In the surplus inversion layer removing step and the residual film etching step, a high-density plasma etching apparatus NE-550 manufactured by ULVAC is used. These steps are executed using CF₄/CHF₃ mixed gas plasma and O₂/Ar mixed gas plasma, respectively.

A case where the T-111 layer that is the processing target layer can be processed until the silicon substrate surface is exposed in the processing target layer processing step is indicated by o, and a case where a failure such as disappearance of the cured film before the substrate surface is exposed occurs is indicated by x in Table 2.

The result shows that, in the inversion process of the present disclosure using a curable composition having an OP of 3.00 or less, the same processing performance as a conventional inversion process using a spin-on-carbon (SOC) layer can be obtained.

### <Volatility: Inkjet Method>

Curable compositions (AC5), and (A7) to (A10) shown in Table 3 are adjusted in accordance with the following procedure. Components (a) to (c) shown in Table 3 are mixed. Next, a component (d) is added such that the content of the component (d) is 80 vol % with respect to the content (20 vol %) of the mixture of the components (a) to (c), thereby obtaining the curable composition (A) having a total content of 100 vol %.

TABLE 3

| | Comparative | | | | |
|---|---|---|---|---|---|
| | Example 5 | Example | Example | Example | Example |
| | (AC5) | 7 (A7) | 8 (A8) | 9 (A9) | 10 (A10) |
| Component | a2/100 | a1/100 | a3/100 | a4/100 | a5/100 |
| (a)/parts by | | | | | |
| weight | | | | | |
| Component | b1/5 | ← | ← | ← | ← |
| (b)/parts by | | | | | |
| weight | | | | | |
| Component | none | ← | ← | ← | ← |
| (c)/parts by | | | | | |
| weight | | | | | |
| Total | 20 | ← | ← | ← | ← |
| vol % of | | | | | |
| components | | | | | |
| (a) to (c) | | | | | |
| Component | d2/80 | ← | ← | ← | ← |
| (d)/vol % | | | | | |
| 80° C. vapor | 0.0024 | 0.0006 | 0.0004 | <0.0001 | <0.0001 |
| pressure of (a) | | | | | |
| Film decrease | x | ○ | ○ | ○ | ○ |

Spin on glass (SOG, T-111 manufactured by Honeywell) is deposited as a processing target layer having a thickness of 300 nm on a silicon substrate, and an adhesion layer described in PTL 4 is deposited as an adhesion layer having a thickness of 5 nm on the surface of the T-111 layer. For the curable compositions (AC5), and (A7) to (A10) shown in Table 3, the arranging step to the separation step are executed on the substrate. In the waiting step, the baking step is executed on a hot plate at 80° C. for 60 sec. The film thickness of the curable composition is measured before the after the baking step. A film decrease of 10 nm or more is indicated by o, and a film decrease less than 10 nm is indicated by x in Table 3.

The result demonstrate that the polymerizable compound (a) whose vapor pressure at 80° C. is 0.001 mmHg or less can prevent volatilization at the time of baking step.

### <Volatility: Spin Coating Method>

Curable compositions (AC6), and (A11) to (A14) shown in Table 4 are adjusted in accordance with the following procedure. Components (a) to (c) shown in Table 4 are mixed. Next, a component (d) is added such that the content of the component (d) is 90 vol % with respect to the content (10 vol %) of the mixture of the components (a) to (c), thereby obtaining the curable composition (A) having a total content of 100 vol %.

TABLE 4

| | Compar- | | | | |
|---|---|---|---|---|---|
| | ative | | | | |
| | Example | Example | Example | Example | Example |
| | 6 (AC6) | 11 (A11) | 12 (A12) | 13 (A13) | 14 (A14) |
| Component | a2/100 | a1/100 | a3/100 | a4/100 | a5/100 |
| (a)/weight by | | | | | |
| parts | | | | | |
| Component | b1/5 | ← | ← | ← | ← |
| (b)/weight by | | | | | |
| parts | | | | | |
| Component | none | ← | ← | ← | ← |
| (c)/weight by | | | | | |
| parts | | | | | |
| Total | 10 | ← | ← | ← | ← |
| vol % of | | | | | |
| components | | | | | |
| (a) to (c) | | | | | |
| Component | d2/90 | ← | ← | ← | ← |
| (d)/vol % | | | | | |
| 80° C. vapor | 0.0024 | 0.0006 | 0.0004 | <0.0001 | <0.0001 |
| pressure of (a) | | | | | |
| Film decrease | x | ○ | ○ | ○ | ○ |

Spin on glass (SOG, T-111 manufactured by Honeywell) is deposited as a processing target layer having a thickness of 300 nm on a silicon substrate, and an adhesion layer described in PTL 4 is deposited as an adhesion layer having a thickness of 5 nm on the surface of the T-111 layer. For the curable compositions (AC6), and (A11) to (A14) shown in Table 4, the arranging step to the separation step are executed on the substrate. In the waiting step, the baking step is executed on a hot plate at 80° C. for 60 sec. The film thickness of the curable composition is measured before the after the baking step. A film decrease of 10 nm or more is indicated by o, and a film decrease less than 10 nm is indicated by x in Table 4.

The result demonstrate that the polymerizable compound (a) whose vapor pressure at 80° C. is 0.001 mmHg or less can prevent volatilization at the time of baking step.

According to the above embodiments, it is possible to provide a new technique concerning a pattern forming method and an article manufacturing method.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. A pattern forming method comprising:
an arranging step of arranging, on a substrate, a curable composition (A) containing at least a polymerizable compound (a);
a contact step of, after the arranging step, bringing the curable composition (A) on the substrate into contact with a mold having unevenness;
a curing step of, after the contact step, curing the curable composition (A) to form a cured film; and
a separation step of, after the curing step, separating the curable composition (A) and the mold, characterized in that
a thickness of a residual film sandwiched between the substrate and a most projecting portion of the concave-convex pattern of the mold is not less than 50 nm, and a height difference of the unevenness of the mold is not more than the thickness of the residual film, and
the pattern forming method further comprises:
a forming step of forming an inversion layer on unevenness transferred from the mold onto the cured film;
a removing step of, in a state in which the inversion layer is buried in a concave portion of the unevenness formed on the cured film, removing an upper layer portion of the inversion layer such that a top surface of a convex portion of the unevenness formed on the cured film is exposed; and
an etching step of, using the inversion layer buried in the concave portion as a mask, etching the cured film up to a surface of the substrate to form an inverted pattern.

2. The pattern forming method according to claim 1, wherein in the arranging step, a plurality of droplets of the curable composition (A) are discretely arranged on the substrate using an inkjet method.

3. The pattern forming method according to claim 2, wherein
the curable composition (A) contains at least a solvent (d),
the polymerizable compound (a) contains at least a compound having one of an aromatic structure, an aromatic heterocyclic structure, and an alicyclic structure,
the curable composition (A) has a viscosity of not less than 2 mPa·s and not more than 60 mPa·s at 23° C.,
in a state in which the solvent is excluded, the curable composition (A) has a viscosity of not less than 30 mPa·s and not more than 10,000 mPa·s at 23° C., and
a content of the solvent with respect to a whole of the curable composition (A) is not less than 70 vol % and not more than 95 vol %.

4. The pattern forming method according to claim 1, wherein
the curable composition (A) contains at least a solvent (d), and
a spin coating method is used in the arranging step.

5. The pattern forming method according to claim 1, wherein
letting N be the number of all atoms in a molecule, N_{C} be the number of carbon atoms in the molecule, and N_{O} be the number of oxygen atoms in the molecule,
an Ohnishi Parameter (OP) that is a molar fraction weighted average value of an N/(N_{C}−N_{O}) value of the molecule of each of polymerizable compounds (a) that may include a plurality of types is not less than 2.00 and not more than 3.00.

6. The pattern forming method according to claim 1, wherein a vapor pressure of each of the polymerizable compounds (a), which may include a plurality of types, at 80° C. is not more than 0.001 mmHg.

7. The pattern forming method according to claim 1, wherein a processing target layer on an uppermost layer of the substrate is an insulating film containing at least silicon atoms.

8. The pattern forming method according to claim 1, further comprising a waiting step of, after the arranging step, waiting for a predetermined time before a start of the contact step.

9. An article manufacturing method comprising:
a step of forming a pattern of a curable composition on a substrate using a pattern forming method defined in claim 1; and
a step of processing the substrate on which the pattern is formed in the step,
wherein an article is manufactured from the processed substrate.
